(19) United States
(12) Patent Application Publication
(10) Pub. No.: US 2023/0410315 A1
(43) Pub. Date: Dec. 21, 2023

(54) DEEP MAGNETIC RESONANCE FINGERPRINTING AUTO-SEGMENTATION

(71) Applicant: MEMORIAL SLOAN KETTERING CANCER CENTER, New York, NY (US)

(72) Inventors: Ouri Cohen, New York, NY (US); Ricardo Otazo, New York, NY (US); Harini Veeraraghavan, New York, NY (US)

(21) Appl. No.: 18/250,955

(22) PCT Filed: Oct. 25, 2021
(86) PCT No.: PCT/US2021/056483

§ 371 Date: Apr. 27, 2023

Related U.S. Application Data
(60) Provisional application No. 63/106,641, filed on Oct. 28, 2020.

(51) Int. Cl. G06T 7/11; G06T 7/00

(52) U.S. Cl. CPC G06T 7/11; G06T 7/0012; G06T 2207/20084; G06T 2207/20081; G06T 2207/10088

(57) ABSTRACT

Systems and methods are provided for predictive volumetric and structural evaluation of petroleum product containers. The system includes a computing device in communication with data input devices and implementation tools including calibration devices for measuring tank volume among other physical parameters bearing on tank volume. The computing device receives sets of historical physical parameter data for a plurality of tanks and, using machine learning (ML), generates predictive ML models for estimating volumetric parameters of tanks. The predictive model is applied by the system to historical and current data values to estimate current volumetric parameters for a given tank and, based on the results, the system performs or coordinates further operations for the given tank using an implementation tool. The further opera ions can include inventory management, physical calibration, maintenance and inspection as well as system evaluation and control operations.

### CROSS REFERENCE TO RELATED APPLICATIONS

The present application claims priority to U.S. Provisional Application No. 63/106,641, titled “Deep Magnetic Resonance Fingerprinting Auto-Segmentation,” filed Oct. 28, 2020, which is incorporated herein in its entirety.

### BACKGROUND

A computing device may use computer vision techniques to detect various objects within an image. For certain images, it may be difficult to accurately and reliable segment such objects in an automated manner.

### SUMMARY

At least one aspect of the present disclosure is directed to systems and methods of training models to segment tomographic images. A computing system may identify a training dataset. The training dataset may have: a plurality of sample tomographic images derived from a section of a subject, a plurality of tissue parameters associated with the section of the subject corresponding to the plurality of sample tomographic images, and an annotation identifying at least one region on the section of the subject in at least one of the plurality of sample tomographic images. The computing system may train an image segmentation model using the training dataset. The image segmentation model may include a generator to determine a plurality of acquisition parameters using the plurality of sample tomographic images. The plurality of acquisition parameters may define an acquisition of the plurality of sample tomographic images from the section of the subject. The image segmentation model may include an image synthesizer to generate a plurality of synthesized tomographic images in accordance with the plurality of tissue parameters and the plurality of acquisition parameter. The image segmentation model may include a discriminator to determine a classification result indicating whether an input tomographic image corresponding to one of the plurality of sample tomographic image or the plurality of synthesized tomographic images is synthesized. The image segmentation model may include a segmentor to generate, using the input tomographic image, a segmented tomographic image identifying the at least one region on the section of the subject. The computing system may store the image segmentation model for use to identify one or more regions of interest in the tomographic images.

In some embodiments, the computing system may train the image segmentation model by determining a segmentation loss metric based on the segmented tomographic image and the annotation. In some embodiments, the computing system may train the image segmentation model by updating one or more parameters of at least one of the generator, the discriminator, and the segmentor of the image segmentation model using the segmentation loss metric.

In some embodiments, the computing system may train the image segmentation model by determining a matching loss metric based on the plurality of sample tomographic image and the corresponding plurality of synthesized tomographic image. In some embodiments, the computing system may train the image segmentation model by updating one or more parameters of at least one of the generator, the discriminator, and the segmentor of the image segmentation model using the matching loss metric. In some embodiments, the computing system may train the image segmentation model by updating one or more parameters of at least one of the generator and the discriminator using a loss metric associated with the segmentor.

In some embodiments, the computing system may provide, responsive to training of the image segmentation model, the plurality of acquisition parameters for acquisition of the tomographic images. The plurality of acquisition parameters may identify at least one of a flip angle (FA), a repetition time (TR), or an echo time (TE).

In some embodiments, the segmentor of the image segmentation model may include a plurality of residual layers corresponding to a plurality of resolutions to generate the segmented tomographic image. Each of the plurality of residual layers may have one or more residual connection units (RCUs) to process at least one feature map for a corresponding resolution of the plurality of resolutions.

In some embodiments, each of the plurality of sample tomographic images may be acquired from the section of the subject in vivo via magnetic resonance imaging. The plurality of tissue parameters may identify at least one of proton density (PD), a longitudinal relaxation time (T1), or a transverse relaxation time (T2) for the acquisition of the first tomographic image.

At least one aspect of the present disclosure is directed to systems and methods of segmenting tomographic images. A computing system may identify a plurality of acquisition parameters derived from training of an image segmentation model and defining an acquisition of tomographic images. The computing system may receive a plurality of tomographic images of a section of a subject using the plurality of acquisition parameters and a plurality of tissue parameters. The plurality of tissue parameters may be associated with the section of the subject corresponding to the plurality of tomographic images. The section of the subject may have at least one region of interest. The computing system may apply the image segmentation model to the plurality of tomographic images to generate a segmented tomographic image. The computing system may apply store the segmented tomographic image identifying the at least one region of interest on the section of the subject

In some embodiments, the computing system may establish the image segmentation model comprising a generator to determine the plurality of acquisition parameters, an image synthesizer to generate at least one synthesized tomographic image, a discriminator to determine whether an input tomographic image is synthesized, using a training dataset. The training dataset may include a sample tomographic image and an annotation identifying at least one region of interest within the sample tomographic image. In some embodiments, the computing system may update one or more parameters of the generator, the discriminator, and the segmentor using a loss metric. The loss metric may include at least one of a segmentation loss metric or a matching loss metric.

In some embodiments, the computing system may apply a segmentor of the image segmentation model to the tomographic image, without applying a generator, an image synthesizer, and a discriminator used to train the image segmentation model based on a training dataset. In some embodiments, the image segmentation model may include a segmentor. The segmentor may include a plurality of residual layers corresponding to a plurality of resolutions to generate the segmented tomographic image. Each of the plurality of residual layers may have one or more residual connection units (RCUs) to process at least one feature map for a corresponding resolution of the plurality of resolutions.

In some embodiments, the computing system may provide, to a magnetic resonance imaging (MRI) device, the plurality of acquisition parameters for the acquisition the tomographic image. The plurality of acquisition parameters may identify at least one a flip angle (FA), a repetition time (TR), or an echo time (TE). The plurality of tissue parameters may identify at least one of a proton density (PD), a longitudinal relaxation time (T1), or a transverse relaxation time (T2).

### BRIEF DESCRIPTION OF THE DRAWINGS

FIG. 1 depicts a block diagram of a system for training of deep magnetic resonance (MR) fingerprinting auto-segmentation, in accordance with an illustrative embodiment;

FIG. 2A depicts a block diagram of a deep-learning segmentation network in the system for training deep-MR fingerprinting auto-segmentation, in accordance with an illustrative embodiment;

FIG. 2B depicts a block diagram of a residual connection unit in the deep-learning segmentation network, in accordance with an illustrative embodiment;

FIG. 3 depicts a set of segmented images produced from MRI T1-weighted and T2-weight contrast images using different approaches, in accordance with an illustrative embodiment;

FIG. 4 depicts a block diagram of a system for segmenting tomographic images in accordance with an illustrative embodiment;

FIG. 5 depicts a block diagram of a tomograph in the system for segmenting tomographic images in accordance with an illustrative embodiment;

FIG. 6 depicts a block diagram of an image segmentation model in the system for segmenting tomographic images in accordance with an illustrative embodiment;

FIG. 7A depicts a block diagram of a generator in the system for segmenting tomographic images in accordance with an illustrative embodiment;

FIG. 7B depicts a block diagram of an encoder in the generator in the system for segmenting tomographic images in accordance with an illustrative embodiment;

FIG. 7C depicts a block diagram of a convolution stack in the encoder of the generator in the system for segmenting tomographic images in accordance with an illustrative embodiment;

FIG. 7D depicts a block diagram of a decoder in the generator in the system for segmenting tomographic images in accordance with an illustrative embodiment;

FIG. 7E depicts a block diagram of a deconvolution stack of the decoder in the generator in the system for segmenting tomographic images in accordance with an illustrative embodiment;

FIG. 8 depicts a block diagram of an image synthesizer in the image segmentation model in the system for segmenting tomographic images in accordance with an illustrative embodiment;

FIG. 9A depicts a block diagram of a discriminator in the image segmentation model in the system for segmenting tomographic images in accordance with an illustrative embodiment;

FIG. 9B depicts a block diagram of a convolution stack in the discriminator in the image segmentation model in the system for segmenting tomographic images in accordance with an illustrative embodiment;

FIG. 10A depicts a block diagram of a segmentor in the image segmentation model in the system for segmenting tomographic images in accordance with an illustrative embodiment;

FIG. 10B depicts a block diagram of a residual connection unit (RCU) block in the segmentor in the image segmentation model in the system for segmenting tomographic images in accordance with an illustrative embodiment;

FIG. 10C depicts a block diagram of a residual connection unit (RCU) in a RCU block in the segmentor in the image segmentation model in the system for segmenting tomographic images in accordance with an illustrative embodiment;

FIG. 10D depicts a block diagram of a set of residual layers in a segmentor in the image segmentation model in the system for segmenting tomographic images in accordance with an illustrative embodiment;

FIG. 11 depicts a block diagram of configuring the tomograph upon establishment of the image segmentation model in the system for segmenting tomographic images in accordance with an illustrative embodiment;

FIG. 12A depicts a flow diagram of a method of training models to segment tomographic images in accordance with an illustrative embodiment;

FIG. 12B depicts a flow diagram of a method of applying models to segment tomographic images in accordance with an illustrative embodiment; and

FIG. 13 depicts a block diagram of a server system and a client computer system in accordance with an illustrative embodiment.

### DETAILED DESCRIPTION

Following below are more detailed descriptions of various concepts related to, and embodiments of, systems and methods for segmenting tomographic images. It should be appreciated that various concepts introduced above and discussed in greater detail below may be implemented in any of numerous ways, as the disclosed concepts are not limited to any particular manner of implementation. Examples of specific implementations and applications are provided primarily for illustrative purposes.

Section A describes an approach for deep magnetic resonance fingerprinting auto-segmentation.

Section B describes systems and methods for systems and methods for training deep-learning models to segment tomographic images and segmenting tomographic images using deep-learning models.

Section C describes a network environment and computing environment which may be useful for practicing various computing related embodiments described herein.

### A. Deep Magnetic Resonance Fingerprinting Auto-Segmentation

Segmentation of tumors and organs at risk from MR images is a part of successful radiation treatment planning, which can include offline planning (before the treatment session) and online planning (during the treatment session using the recently introduced MRI-Linac systems). Manual segmentation by radiologists is time consuming, susceptible to errors and can be particularly inefficient for the case of online treatment planning. Conversely, despite the tremendous success in automated segmentation techniques using deep learning, the accuracies particularly for tumors fall short of the acceptable levels due in part to a lack of sufficient MRI contrast to distinguish structures from background as well as a lack of sufficiently large training sets.

The focus of the present disclosure rests on leveraging MRI contrast. If the MRI contrast between tumor or organ and the background is improved, segmentation becomes an easier task. In other words, if the contrast between tumor and background is easily discernable on MM, the features for differentiating tumor from background can be more easily extracted despite training data size limitations. There is hence a desire for a robust automatic MR contrast enhanced automated segmentation technique of tumors and organs at risk.

Although various deep machine learning techniques have enabled significant accuracy improvements in segmentation compared to machine learning methods, such approaches may be impacted by scanner variations that may alter the contrast of the foreground and background voxels in the images, in particular for conventional MRI. An alternative to conventional MRI is MR fingerprinting (MRF). MRF acquires quantitative tissue parameters, which are not affected by scanner variations. The main claim of this disclosure is to combine deep learning and MRF to learn the underlying imaging parameters that produce the optimal MR contrast to maximize segmentation accuracy.

An additional benefit of the approach is its computational tractability. Rather than estimating the distribution of MRI signal intensities across an entire image, as is done with other approaches, the present method may use estimation of a fixed set of scalar MRI parameters, significantly simplifying the problem. Estimating the distribution of MRI intensities is challenging because some structures with distinct imaging contrasts may not be accurately modeled, leading to the so called “hallucination” problem and a potential loss of structures like tumors in the deep learning synthesis. Other approaches may use of specific constraints on the segmented structures to ensure that the shape of the structures (with some average MR intensity for the whole structure) is preserved, or learn a disentangled feature representation to extract the same features irrespective of the differences in image contrasts.

Presented herein the use of an architecture that combines MR parameters learning with segmentation. While other approaches have used deep learning to synthesize MR contrasts, none have been combined with automated segmentation for MR-guided radiation therapy. The systems and methods presented herein is an approach to do a fully integrated MR fingerprinted segmentation system for MR guided radiation therapy treatments.

MR fingerprinting (MRF) is a novel method for rapid acquisition of quantitative tissue parameter maps. Unlike conventional MRI, the quantitative maps reflect the underlying physiological tissue parameters, which are not affected by instrumental variations. The image contrast in MRI is a result of the interplay between the underlying tissue parameters (T1, T2, etc.) and the pulse sequence acquisition parameters. The MRI acquisition process is governed by a set of known equations—the Bloch equations. If the underlying tissue parameters are known, an MR acquisition can be simulated by calculating the effects of RF pulses and gradients on the tissue parameters. By modifying the acquisition parameters governing the pulse sequence (flip angle (FA), repetition time (TR), echo time (TE) etc.) any desired image contrast can be synthesized in post-processing without requiring additional scans. Moreover, judicious selection of the acquisition parameters can enhance contrast between different tissue types such as gray and white matter or healthy and diseased tissue.

Domain adaptation techniques in medical image analysis and in computer vision aim to solve the problem of learning to extract a common feature representation that can be applied to one or more imaging domains (such as varying imaging contrasts) to successfully segment on all domains. The focus of these works has typically been to successfully generalize to imaging modalities that differ slightly from the modality on which the model was trained to accommodate different MR contrasts arising from differences in scanner parameters or X-rays, be scalable across images used in training and testing (such as simulated images used in training, and images from video cameras under different illumination conditions for testing) for modeling diverse imaging conditions (e.g. daytime vs. Nighttime vs. Raining etc).

Approaches in medical image analysis have also considered and developed solutions for using one imaging modality (such as computed tomography) to help in the segmentation of a different imaging modality (like MM) when there are few or no expert labels available for training a deep learning model. Examples include new deep learning approaches using disentangled representations. These methods extract domain-specific attribute (e.g. textural, contrast, and edge appearances) features and domain-agnostic content (such as common high-level spatial organization of organs in all the considered imaging domains) features. These methods were developed for cardiac CT and MRI, abdomen organs CT and MRI and for tumor and normal organ segmentations for MR guided radiotherapy. None of the above methods consider the problem from the perspective of using the deep learning to extract the best possible MR contrast for individual structures to generate a consistent and accurate segmentation.

The systems and methods described herein may leverage the power of MRF to obtain rapid tissue maps to improve auto-segmentation of tumors and organs at risk. The premise of the method is that images are easier to segment when the signal intensity differences between the structure of interest and its surrounding background are large. When performing segmentations using clinically available MRI acquired using specific imaging protocols, the imaging variations may be appropriate for segmenting some of the organs but not all the organs at risk. Acquisition parameters are often optimized in coordination with the radiologists to produce the sequence that can be best interpreted visually by the radiologists. Finding the set of acquisition parameters that will yield MR images with optimal contrast for each segmented tumor and organ at risk structures is challenging because of the large number of parameters involved.

The approach provides an automated way to extract the different sets of optimal acquisition parameters and facilitate segmentation of the tumor and multiple organ at risk structures. These parameters will be modeled as latent vectors that will be jointly learned with a segmentation network. The implementation itself will combine generative adversarial network (GAN) with segmentation architecture framework with losses and constraints to regularize these networks. In practice, the losses and constraints using this framework can be applied to any specific GAN (such as CycleGAN, disentangled representations using variational auto-encoders), and segmentation networks such as commonly used U-net, dense fully convolutional networks, and deeper architectures like the proposed multiple resolution residual networks, among others. In other words, the focus is on the framework (combining generator-discriminator-segmentor), and the regularization constraints or losses used for MRF based segmentation.

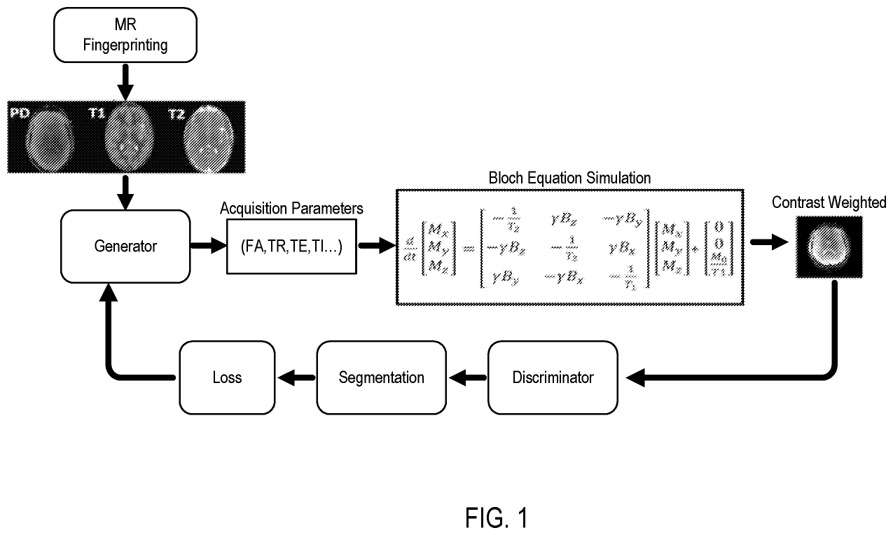

Referring now to FIG. 1, depicted is a block diagram of a system for training of deep magnetic resonance (MR) fingerprinting auto-segmentation. the present framework may be implemented using a variational auto-encoder using a disentangled feature representation to model the contrast parameters for producing organ/tumor specific MR contrast images, and a multiple resolution deep residual network (MRRN) for segmentation.

MR Fingerprinting: A set of N tumor patients is scanned with the MRF sequence and the underlying MR tissue parameters (PD, T1, T2, etc.) extracted. This data will form the training set for the subsequent neural networks.

Generator: The GAN network may include a generator comprised of a sequence of convolutional layer encoders to extract the features from the images, a decoder that produces a set of MR parameters, which are matched by a variational auto-encoder to a latent code prior. The latent code prior is learned from the input data and is optimized such that the segmentation accuracies are maximized for all segmented organs. In other words, the generator samples the distribution of acquisition parameters. These parameters are then used to generate a contrast-weighted image by simulating an acquisition using the Bloch equations and the quantitative tissue parameters.

Discriminator: The discriminator is trained in an adversarial manner such that its loss is minimized when the loss for the generator is maximized. In other words, the discriminator tries to determine if an MR contrast weighted image is real (as seen in set of standard MR contrast images like T1 weighted, T2 weighted, etc.) or are fake (that is produced by using the MR parameters extracted by the generator and combined using the Bloch equations). This is necessary to ensure that the produced images are realistic and are useful for diagnostic purposes as well as segmentation.

The discriminator may combine the segmentation results with the generated images as a joint distribution of image and the segmentation. Other approaches have used images and a scalar classification output or a scalar latent variable but never a pair of images as proposed in this invention. An approach may be implemented for performing unsupervised cross-modality segmentation using CT labeled datasets to segment MR image sets for lung tumor, abdomen organs, and head and neck parotid gland datasets. This approach shows more accurate results than other approaches.

Loss: We will use a jointly trained generator-discriminator-segmentor network. All networks will be optimized using losses computed for image generation, discrimination, and segmentation. The generator and discriminator will be trained in an adversarial manner so that each network tries to improve at the cost of the other network. The losses used for training the two networks will include the distribution matching losses between multiple MR contrast weighted sequences available using standard imaging protocols and the generated contrasts, the joint distribution of segmentation and image matching losses to focus the contrast generation to improve figure-ground segmentation, prior distribution (of the variation auto-encoder) losses computed using Kullback-Leibler divergences (for each of the individual parameters that are assumed to follow a Gaussian prior including a mean and a standard deviation), and the structure segmentation losses computed by maximizing the overlap in the segmented regions between the radiologist-provided segmentation and the algorithm generated segmentation.

In detail, the distribution matching loss will use mathematically robust Wasserstein distance metrics to ensure stable network convergence. This loss computes the differences between the generated and the expected target (including multiple MR contrast sequences) by capturing the finer modes in the distribution. It is particularly suited when the MR sequence has multiple modes as opposed the standard Kulback-Leibler based average distribution matching loss that only matches the peak of the MR intensity histogram. As the goal is to approximate the contrast to any of the real MR contrast sequences, the minimum distance to those sequences will be used. The joint-distribution matching will combine the MR contrast image and the segmentation as a multi-channel image and the matching will be done to minimize the distance of this multi-channel image with respect to any of the target MRI contrast image and the corresponding segmentation produced using the segmentation network.

The segmentation loss will be computed using cross-entropy loss to minimize the voxel-wise errors in the segmentation for multiple organs and tumor, as well as boundary-weighted losses to weight the losses in the boundary more than in the center of the organs.

After training to convergence, the acquisition parameters sampled by the trained generator provide the optimal parameters for maximizing tumor segmentation quality. These parameters can then be used prospectively on new and unseen tumor patient data. Simultaneously, the trained discriminator provides the optimal segmentation algorithm for this data.

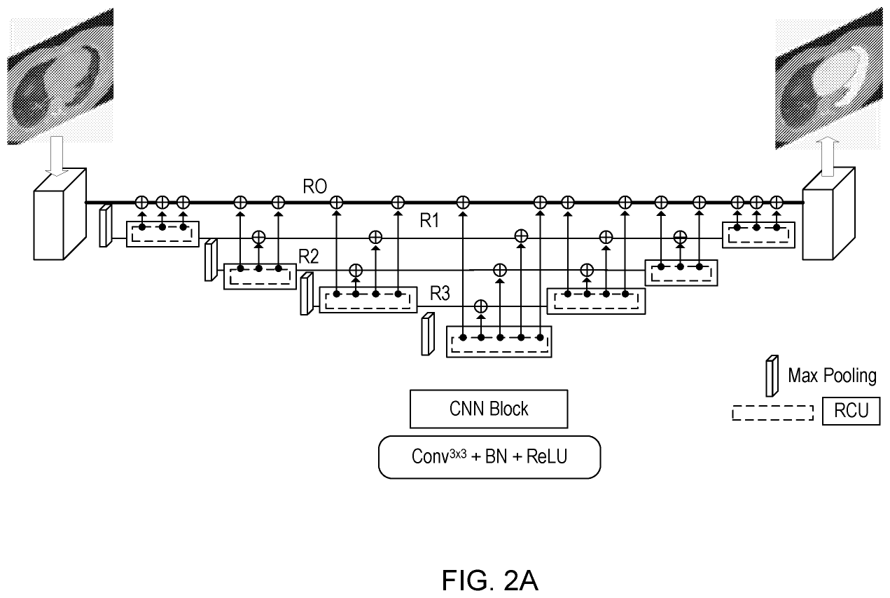

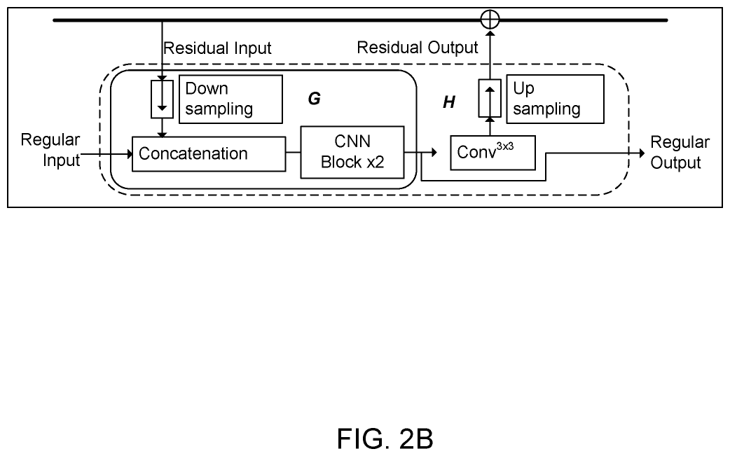

Referring now to FIGS. 2A and 2B, shown is a block diagram of the MRRN network that was used for producing normal organ at risk segmentation for thoracic organ at risk structures from CT image sets. The framework allows for any segmentation architecture to be used. A deep network architecture based on the multiple resolution residual network (MRRN) may be used in some implementations. This network may include multiple residual feature streams that carry image features computed at various image resolutions. These features are connected residually (by adding the features) to the convolutional layer inputs in each layer to incorporate additional information from the individual feature streams. In addition, each layer also receives a residual input from the input of the previous layer. This increases the set of connections and thereby the capacity of the network and its ability to ensure stable convergence by back-propagating losses from the output end to the input end without loss of gradients.

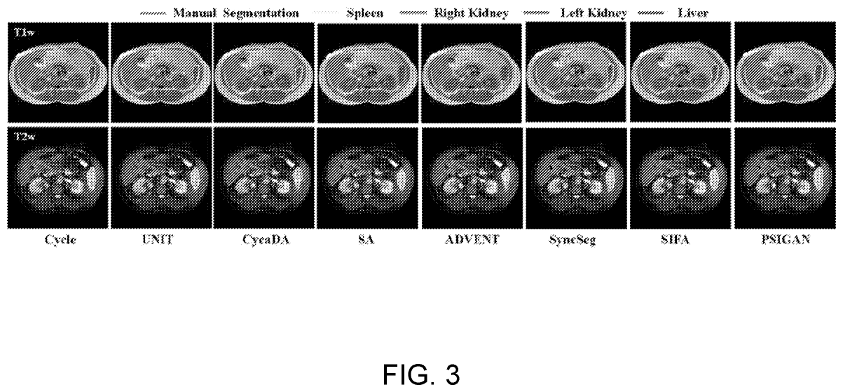

Referring now to FIG. 3, shown are representative examples of abdomen organ segmentation using the joint-density discriminator technique called probabilistic segmentation and image based generator adversarial network (PSIGAN) for learning to segment MRI images without any labeled examples from MRI. Comparisons to multiple state-of-the-art methods, together with the achieved Dice similarity coefficient (DSC) accuracy is shown. The average DSC computed over all the four organs is shown for conciseness.

### B. Systems and Methods for Training Deep-Learning Models to Segment Tomographic Images and Segmenting Tomographic Images Using Deep-Learning Models

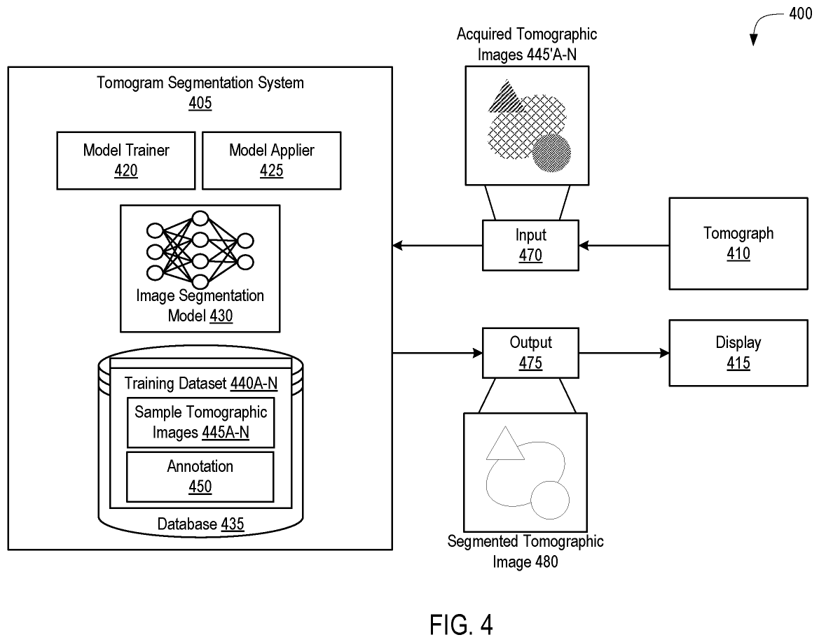

Referring now to FIG. 4, depicted is a block diagram of a system 400 for segmenting tomographic image. In overview, the system 400 may include at least one tomogram segmentation system 405, at least one tomograph 410, and at least one display 415, among others. The tomogram segmentation system 405 may include at least one model trainer 420, at least one model applier 425, at least one image segmentation model 430, and at least one database 435, among others. The database 435 may include one or more training datasets 440A-N (hereinafter generally referred to as training dataset 440). Each training dataset 440 may include a set of sample tomographic images 445A-N (hereinafter generally referred to as tomographic images 445) and at least one annotation 450, among others. In some embodiments, the tomograph 410 and the display 415 may be separate from or a part of the tomograph segmentation system 405. Each of the components in the system 400 listed above may be implemented using hardware (e.g., one or more processors coupled with memory) or a combination of hardware and software as detailed herein in Section C. Each of the components in the system 400 may implement or execute the functionalities detailed herein in Section A.

In further detail, the tomogram segmentation system 405 itself and the components (such as the model trainer 420, the model applier 425, and the image segmentation model 430) may have a training mode and a runtime mode (sometimes referred herein as an evaluation or inference mode). Under the training mode, the tomogram segmentation system 405 may train or establish the image segmentation model 430 using the training dataset 440. In particular, the model trainer 420 may initiate, establish, and maintain the image segmentation model 430 using the sample tomographic images 445 and the annotation 450 of the training dataset 440. Under runtime mode, the tomogram segmentation system 405 may identify, retrieve, or otherwise receive at least one set of acquired tomographic images 445′A-N (hereinafter generally referred to as acquired tomographic images 445′) in at least one input 470 from the tomograph 410. In addition, the tomogram segmentation system 405 may generate a segmented tomographic image 480 using the set of acquired tomographic images 445′ to provide for presentation on the display 415. The sample tomographic images 445 may be derived from the acquired tomographic images 445′. In discussing the system 400, both the sample tomographic images 445 and the acquired tomographic images 445′ are referred to generally as tomographic images 445.

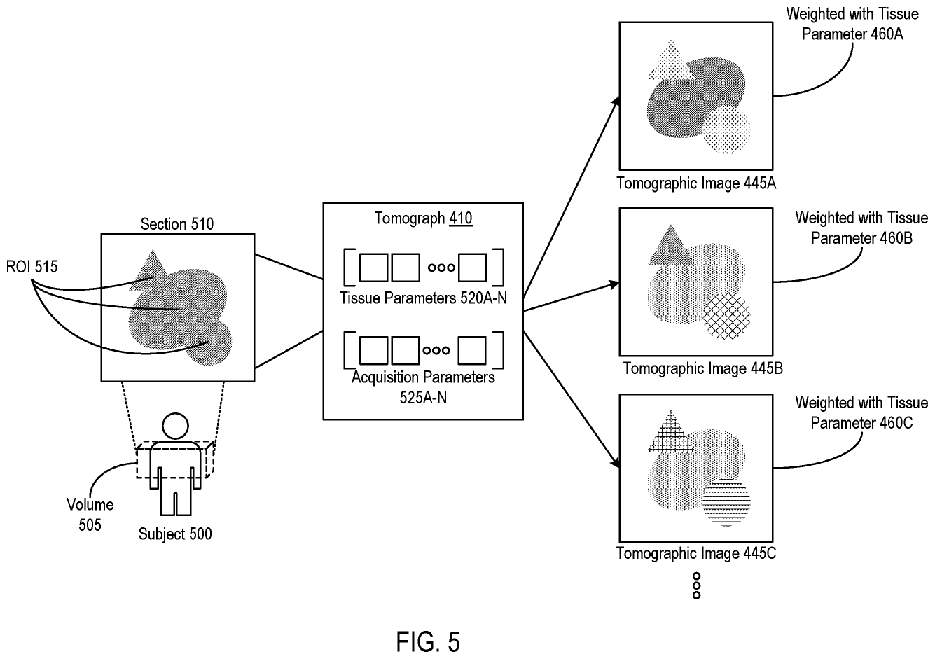

Referring now to FIG. 5, depicted is a block diagram of the tomograph 410 (also referred herein as an imaging device or an image acquisition device) in the system 400. The tomograph 410 may produce, output, or otherwise generate one or more tomographic images 445 (e.g., tomographic images 445A-C as depicted) in accordance with a tomographic imaging technique. The tomograph 410 may be, for example, a magnetic resonance imaging (MRI) scanner, a nuclear magnetic resonance (NMR) scanner, X-ray computed tomography (CT) scanner, an ultrasound imaging scanner, and a positron emission tomography (PET) scanner, and a photoacoustic spectroscopy scanner, among others. The tomographic imaging technique used by the tomograph 410 may include, for example, magnetic resonance imaging (MRI), nuclear magnetic resonance (NMR) imaging, X-ray computed tomography (CT), ultrasound imaging, positron emission tomography (PET) imaging, and photoacoustic spectroscopy, among others. The present disclosure discusses the tomograph 410 and the tomographic images 445 primarily in relation to MRI, but the other imaging modalities listed above may be supported by the tomogram segmentation system 405.

The tomograph 410 may image or scan at least one volume 505 of at least one subject 500 in accordance with the tomographic imaging technique in generating the tomographic images 445. For example, to carry out MRI imaging, the tomograph 410 may apply one or more magnetic fields (e.g., an external magnetic field) to the subject 500 in vivo and measure the radiofrequency (RF) signals emitted from the subject 500. The subject 500 may include, for example, a human, an animal, a plant, or a cellular organism, among others. The volume 505 may correspond to a three-dimension portion of the subject 500. For example, the volume 505 may correspond to a head, a torso, an abdomen, a hip, an arm, or a leg portion of the subject 500, among others. Within the volume 505 under scan, the subject 500 may have one or more objects, such as a tissue, an organ, blood vessels, neurons, bone, or other material.

By scanning, the tomograph 410 may acquire, obtain, or otherwise receive one or more sets of data points corresponding to the volume 505 of the subject 500. The sets of data points acquired by the tomograph 410 may be three-dimensional or two-dimensional. The sets of data points may be acquired along at least one section 510 within the volume 505 of the subject 500 (e.g., in vivo). Each section 510 may correspond to a two-dimensional cross-section (e.g., a front, a sagittal, a transverse, or an oblique plane) within the volume 505 of the subject 500. By extension, each set of data points may correspond to a respective section 510 in the volume 505 of the subject 500. At least one section 510 may include one or more regions of interest (ROI) 515. Each ROI 515 may correspond to a particular feature within the volume 505 or section 510 of the subject 500 under scan. The feature may include, for example, a lesion, a hemorrhage, a tumor (benign or malignant), infarction, edema, fat, or bone, among others.

The tomograph 410 may be configured with, store, or include a set of tissue parameters 520A-N (hereinafter referred generally as tissue parameters 520) and a set of acquisition parameters 525A-N (hereinafter referred generally as acquisition parameters 525). The tissue parameters 520 may be associated with one or more objects within the volume 505 or the section 510 of the subject 500. In particular, the tissue parameters 520 may characterize, identify, or otherwise define properties of the object within the volume 505 of the section 510 of the subject 500 in relation to tomographic imaging technique. The acquisition parameters 525 may be associated with the acquisition of the data from the subject 500 under the tomographic imaging technique. In particular, the acquisition parameters 525 may define the operational characteristics of the tomograph 410 in obtaining the data from the subject 500.

The types of parameters in both the tissue parameters 520 and the acquisition parameters 525 may depend on the tomographic imaging technique applied by the tomograph 410. For Mill (e.g., MR fingerprinting), the tissue parameters 520 may include, for example, a proton density (PD), a longitudinal relaxation time (T1) (sometimes referred herein as a spin-lattice time) and a transverse relaxation time (T2) (sometimes referred herein as a spin-spin time), among others. The proton density may identify a quantity of hydrogen nuclei in the volume 505 of tissue within the subject 500. The longitudinal relaxation time may refer to a time constant for spins of the nuclei aligned with the external magnetic field. The transverse relaxation time may refer to a time constant for loss of phase coherence among the spins of the nuclei oriented at a transverse angle to the external magnetic field. In addition, the acquisition parameters 525 may define the RF pulses applied to the subject 500 during scanning of the volume 505. The acquisition parameters 525 may include, for example, a flip angle (FA), a repetition time (TR), and an echo time (TE), among others. The flip angle may indicate an amount of rotation of a macroscopic magnetization vector outputted by the applied RP pulse in relation to the magnetic field. The repetition time may identify an amount of time between a start of a pulse sequence and a start of a succeeding pulse sequence. The echo time may identify a time between an excitation RF pulse and a peak of a spin echo.

With the data acquired from the volume 505 of the subject 500, the tomograph 410 may generate one or more tomographic images 445 in accordance with the tomographic imaging technique. At least a portion of the tomographic image 445 may correspond to the ROI 515 within the volume 505 or section 510 of the subject 500. In some embodiments, each tomographic image 445 may be three-dimensional corresponding to the volume 505 of the subject 500 under scan. When three-dimensional, the tomographic image 445 may include one or more slices corresponding to the scanned sections 510 within the volume 505. In some embodiments, each tomographic image 445 may be two-dimensional corresponding to a section 510 defined in the volume 505 under scan. In some embodiments, the tomograph 410 may generate a set of tomographic images 445 two-dimensions derived from the three-dimensional data points acquired from scanning.

Using the tissue parameters 520 and the acquisition parameters 525, the tomograph 410 may process the measured data points obtained from the scanning of the volume 505 of the subject 500 in generating the tomographic images 445. The tomograph 410 may apply different weights of the tissue parameters 520 in generating the tomographic images 445. In the illustrated example, the tomograph 410 may generate a first tomographic image 445A weighted using a first tissue parameter 460A (e.g., proton density (PD)), a second tomographic image 445B weighted using a second tissue parameter 460B (e.g., longitudinal relaxation time (T1)), and a third tomographic image 445C weighted using a third tissue parameter 460C (e.g., transverse relaxation time (T2)).

Upon generation, the tomograph 410 may send, transmit, or otherwise provide the tomographic images 445 to the tomogram segmentation system 405. In some embodiments, the tomograph 410 may also provide the tissue parameters 520 associated with the tomographic images 445 to the tomogram segmentation system 405. For example, the tomograph 410 may provide the weights of tissue parameters 520 for each of the tomographic images 445 acquired from the subject 500. In some embodiments, the tomograph 410 may send, transmit, or otherwise provide the acquisition parameters 525 to the tomogram segmentation system 405. The acquisition parameters 525 may be common or substantially the same (e.g., less than 10% difference) among the set of tomographic images 445.

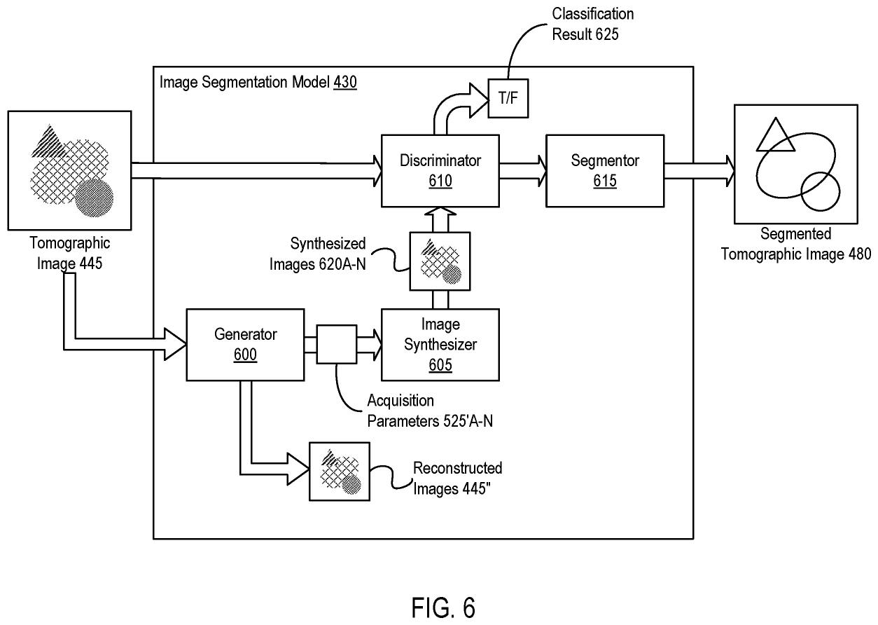

Referring now to FIG. 6, depicted is a block diagram of the image segmentation model 430 in the system 400. The image segmentation model 430 may be configured at least in part as a generative adversarial network (GAN), a variational auto-encoder, or other unsupervised or semi-supervised model, among others. As depicted, the image segmentation model 430 may include at least one generator 600, at least one image synthesizer 605, at least one discriminator 610, and at least one segmentor 615, among others. The image segmentation model 430 may have at least one input and at least one output. The input of the image segmentation model 430 may include one or more of the tomographic images 445 (e.g., from the training dataset 440 or the tomograph 410). The output of the image segmentation model 430 may include at least one segmented tomographic image 480. The segmented tomographic image 480 may identify the one or more ROIs 515 within the corresponding tomographic image 445. The segmented tomographic image 480 may identify the one or more ROIs 515 within the corresponding tomographic image 445.

The components of the image segmentation model 430 may be inter-related to one another in accordance to a defined architecture (also referred herein as a structure). Each of the components in the image segmentation model 430 may have at least one input and at least one output connected to one another. The input of the generator 600 may include the tomographic image 445 provided to the image segmentation model 430. The output of the generator 600 may include a set or reconstructed tomographic images 445″A-N (hereinafter generally referred to as reconstructed tomographic images 445″) and a set of acquisition parameters 525′A-N (hereinafter generally referred to as acquisition parameters 525′). The tomographic images 445 (or reconstructed tomographic images 445″) set of acquisition parameters 525′ may be fed to the input of the image synthesizer 605. The input of the image synthesizer 605 may be connected to the output of the generator 600, and may include the set of acquisition parameters 525′. The output of the image synthesizer 605 may include a set of synthesized tomographic images 620A-N (hereinafter generally referred to as synthesized tomographic images 625). The input of the discriminator 610 may include the tomographic image 445 provided to the image segmentation model 430 or the synthesized tomographic images 620 outputted by the image synthesizer 605. The output of the discriminator 610 may include at least one classification result 625. The input of the discriminator 610 may be fed forward to the input of the segmentor 615. The input of the segmentor 615 may include the tomographic image 445 originally fed into the image segmentation model 430. The output of the segmentor 615 may correspond to the output of the image segmentation model 430, and may include the segmented tomographic image 480.

In each component of the image segmentation model 430, the input and output may be related to each other via a set of parameters to be applied to the input to generate the output. The parameters of the generator 600, the discriminator 610, and the segmentor 615 may include weights, kernel parameters, and neural components, among others. The parameters in the generator 600, the discriminator 610, and the segmentor 615 may be arranged in one or more transform layers. Each transform layer may identify, specify, or define a combination or a sequence of the application of the parameters to the input values. The parameters of the image synthesizer 605 may include a constants, factors, or components, among others. The parameters in the image synthesizer 605 may be applied to the input in accordance with a policy or equation. The parameters may be arranged in accordance with a machine learning algorithm or model in the respective components of the image segmentation model 430.

When in training mode, the model trainer 420 may initiate or establish the image segmentation model 430 (including the generator 600, the discriminator 610, and the segmentor 615) using the training dataset 450. The initiation and the establishment of the image segmentation model 430 may be under the training mode, and the sample tomographic images 445 of the training dataset 450. In establishing the image segmentation model 430, the model trainer 420 may access the database 435 to retrieve, obtain, or otherwise identify the training dataset 440. From each training dataset 440, the model trainer 420 may extract, retrieve, or otherwise identify the set of sample tomographic images 445. The set of sample tomographic images 445 may be derived or acquired from a previous scan of the subject 500 (e.g., the volume 505 or the section 510). Each tomographic image 445 in the set may correspond to different weightings of the tissue parameters 520. In some embodiments, the training dataset 440 may identify or include the set of tissue parameters 520 for each of the tomographic images 445. In some embodiments, the training dataset 440 may identify or include the set of acquisition parameters 525 used to generate the set of tomographic images 445.

From the training dataset 440, the model trainer 420 may retrieve, extract, or otherwise identify the annotation 450. For at least one of the tomographic images 445 in the set, the training dataset 440 may identify or include the annotation 450. In some embodiments, the training dataset 440 may include the annotation 450 for one of the tomographic images 445 with a particular weighting of the tissue parameters 520. For example, the annotation 450 of the training dataset 440 may be associated with the first tomographic image 445A weighted using the first tissue parameter 520. The annotation 450 may label or identify one or more ROIs 515 within the associated tomographic image 445. In some embodiments, the annotation 450 may identify the location of the ROIs 515 (e.g., using pixel coordinates) within the tomographic image 445. In some embodiments, the annotation 450 may identify an outline of the ROIs 515. The annotation 450 may have been manually created. For example, a clinician may manually have examined one of tomographic images 445 for the one or more ROIs 515, and add the annotation 450 with an outline of the ROIs 515 thereon. The annotation 450 may be maintained and stored separately from the tomographic images 445 (e.g., using different files).

With the identification, the model applier 425 may apply the image segmentation model 430 to each tomographic image 445 of the training dataset 440 during training mode. In training mode, the model applier 425 may run and process the tomographic images 445 through the generator 600, the image synthesizer 605, the discriminator 610, and the segmentor 615 of the image segmentation model 430. In runtime mode, the model applier 425 may retrieve, identify, or otherwise receive the tomographic images 445 from the tomograph 410, and apply the image segmentation model 430 to the tomographic images 445. Upon receipt, the model applier 425 may apply at least the segmentor 615 of the image segmentation model 430 to the acquired tomographic images 445.

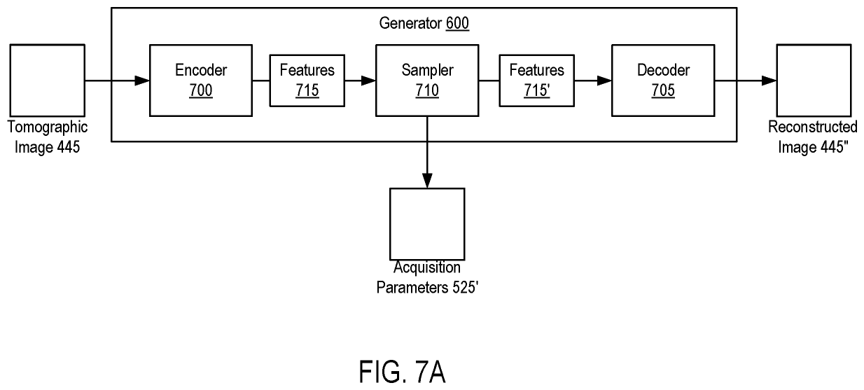

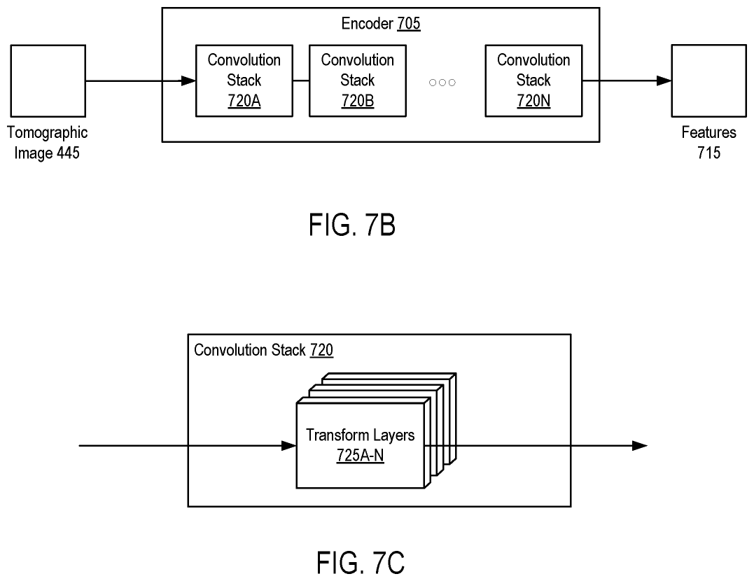

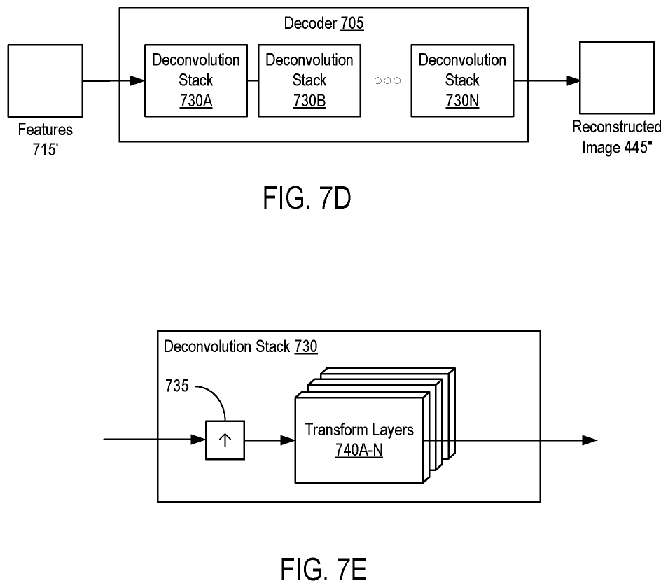

The application of the image segmentation model 430 to the tomographic images 445 may be in accordance with the structural of the image segmentation model 430 (e.g., as depicted). In some embodiments, the model applier 425 may apply the tomographic images 445 individually (e.g., one after another). In applying the image segmentation model 430, the model applier 425 may feed each tomographic image 445 into the input of the image segmentation model 430. The model applier 425 may process the input tomographic image 445 in accordance with the components (e.g., the generator 600, the image synthesizer 605, the discriminator 610, and segmentor 615) and architecture of the image segmentation model 430. The function and structure of the image segmentation model 430 in processing the input and updating the weights of the components is detailed herein below in conjunction with FIGS. 7A-11.

Referring now to FIG. 7A, depicted is a block diagram of the generator 600 (sometimes referred herein as a generator network) of the image segmentation model 430 in the system 400. The generator 600 may include at least one encoder 700, at least one decoder 705, and at least one sampler 710, among others. In some embodiments, the components of the generator 600 may be arranged in accordance with a variational auto-encoder architecture. In some embodiments, the generator 600 may lack the sampler 710. The set of weights of the generator 600 may be arranged in accordance with the encoder 700 and the decoder 705. Within generator 600, the encoder 700, the decoder 705, and the sampler 710 may be connected in series, and each may have at least one input and at least one output. The input of the encoder 700 may correspond to the input of the generator 600, and may include the tomographic image 445. The output of the encoder 700 may include a set of features 715 (also referred herein as latent features or feature map), and may be fed to the sampler 710. The output of the sampler 710 may be connected with the input of the decoder 705. The output of the decoder 705 may correspond to the output of the generator 600, and may include at least one reconstructed tomographic image 445″.

In feeding into the image segmentation model 430, the model applier 425 may provide each tomographic image 445 as the input of the generator 600. The model applier 425 may process the input tomographic image 445 in accordance with the weights of the encoder 700 to produce, output, or otherwise generate the set of features 715. The set of features 715 may correspond to a lower resolution or dimension representation of the tomographic image 445. For example, the set of features 715 may represent latent attributes of the tomographic image 445, and may be partially correlated with the tissue parameters 520 or the acquisition parameters 525. The model applier 425 may feed the set of features 715 forward in the generator 600 to the sampler 710.

Continuing on, the model applier 425 may use the sampler 710 to identify or select one or more features from the set of features 715 as a sampled subset of features 715′. The selection of the features from the set of features 715 may be in accordance with a distribution function (e.g., a probability distribution such as a Gaussian or normal distribution). In some embodiments, the sampler 710 may select the subset of features 715′ using the distribution function. In some embodiments, the sampler 710 may identify one or more distribution characteristics (e.g., mean, variance, and standard deviation) of the values within the set of feature 715. The distribution characteristics may be used by the model applier 425 to select the subset from the set of features 715. In some embodiments, the model applier 425 may use the sampler 710 to identify or select a set of acquisition parameters 525′ from the set of features 715 or the subset of features 715′. The subset of features 715′ selected by the sampler 710 may correspond or represent a distribution of the original tissue parameters 520 or the acquisition parameters 525 used to generate the tomographic image 445. In some embodiments, the model applier 425 may select at least a portion of the subset of features 515′ as the set of acquisition parameters 525′.

Upon sampling, the model applier 425 may apply the decoder 705 to the sampled set of features 715′. Using the weights of the decoder 705, the model applier 425 may process the subset of features 715′ to produce, output, or generate the reconstructed tomographic image 445″. The reconstructed tomographic image 445″ may correspond to the original tomographic image 445 fed into the generator 600. The reconstructed tomographic image 445″ may have a greater dimension than the set of features 715 generated by the encoder 700. The reconstructed tomographic image 445″ may also have the same dimensions (or resolution) as the original tomographic image 445. The model applier 425 may feed the reconstructed tomographic image 445 and the set of acquisition parameters 525

The model trainer 420 may establish and train the generator 600 using the training dataset 440. The model trainer 420 may calculate, generate, or otherwise determine at least one loss metric (also referred herein as a reconstruction loss). The determination of the loss metric may be based on a comparison between the reconstructed tomographic image 445″ and the original tomographic image 445 used to generate the reconstructed tomographic image 445″. The loss metric may indicate or correspond to a degree of deviation between the original tomographic image 445 and the reconstructed tomographic image 445″ (e.g., a pixel-by-pixel value comparison). The loss metric may be calculated in accordance with a loss function, such as a Kullback-Leibler (KL) divergence, a root mean squared error, a relative root mean squared error, and a weighted cross entropy, among others. In general, when the degree of deviation is greater, the loss metric may be also greater. Conversely, when the degree of deviation is lower, the loss metric may be lower.

Using the loss metric, the model trainer 420 may modify, configure, or otherwise update at least one of the weights in the generator 600, such as in the encoder 700 or the decoder 750. The loss metric may be back-propagated to update the weights in the generator 600. The updating of weights may be in accordance with an optimization function (or an objective function) for the generator 600. The optimization function may define one or more rates or parameters at which the weights of the generator 600 are to be updated. For example, the model trainer 420 may use the optimization function with a set learning rate, a momentum, and a weight decay for a number of iterations in training. The updating of the weights may be repeated until a convergence condition.

Referring now to FIG. 7B, depicted is a block diagram of the encoder 700 in the generator 600 in the image segmentation model 430 of the system 400. The encoder 700 may include a set of convolution stacks 720A-N (hereinafter generally referred to as convolution stacks 720). The input and the output of the encoder 700 may be related via a set of parameters define within the set of convolution stacks 720. The set of convolution stacks 720 can be arranged in series or parallel configuration, or in any combination. In parallel configuration, the input of one convolution stacks 720 may include the input of the entire encoder 700. In a series configuration (e.g., as depicted), the input of one convolution stacks 720 may include the output of the previous convolution stacks 720. The input of the first convolution stack 720A may be the tomographic image 445. The output of the last convolution stack 720N may be the set of features 715.

Referring now to FIG. 7C, depicted is a block diagram of the convolution stack 720 in the encoder 700 of the generator 600 in the image segmentation model 430 of the system 400. Each convolution stack 720 may include a set of transform layers 725A-N (hereinafter generally referred to as transform layers 725). The set of transform layers 725 may be arranged in series or parallel configuration, or in any combination. The transform layers 725 may define or include the weights for the corresponding convolution stack 720 in the encoder 700. The set of transform layers 725 can include one or more weights to modify or otherwise process the input to produce or generate an output set of features. For example, the set of transform layers 725 may include at least one convolutional layer, at least one normalization layer, and at least one activation layer, among others. The set of transform layers 725 can be arranged in series, with an output of one transform layer 725 fed as an input to a succeeding transform layer 725. Each transform layer 725 may have a non-linear input-to-output characteristic. In some embodiments, the set of transform layers 725 may be a convolutional neural network (CNN). The convolutional layer, the normalization layer, and the activation layer (e.g., a rectified linear unit (ReLU)) may be arranged in accordance with the CNN architecture.

Referring now to FIG. 7D, depicted is a block diagram of the decoder 705 and the sampler 710 in the generator 600 in the image segmentation model 430 of the system 400. The decoder 705 may include a set of deconvolution stacks 730A-N (hereinafter generally referred to as deconvolution stacks 730). The input and the output of the decoder 705 may be related via a set of parameters define within the set of deconvolution stacks 730. The set of deconvolution stacks 730 can be arranged in series or parallel configuration, or in any combination. In parallel configuration, the input of one deconvolution stacks 730 may include the input of the entire decoder 705. In a series configuration (e.g., as depicted), the input of one deconvolution stacks 730 may include the output of the previous deconvolution stacks 730. The input of the first deconvolution stack 730A may be the set of features 715 generated by the encoder 700 or the sampled set of features 715′ (e.g., as depicted) from the set of features 715. The output of the last deconvolution stack 730N may be the reconstructed tomographic image 445″.

Referring now to FIG. 7E, depicted is a block diagram of each deconvolution stack 730 of the decoder 705 in the generator 600 in the image segmentation model 430 of the system 400. The deconvolution stack 730 may include at least one sampler 735 and a set of transform layers 740A-N (hereinafter generally referred to transform layers 740). The up-sampler 735 and the set of transform layers 740 can be arranged in series (e.g., as depicted) or parallel configuration, or in any combination. The up-sampler 735 may increase the image resolution of the input to increase a dimension (or resolution) to fit the set of transform layers 740. In some implementations, the up-sampler 735 can apply an up-sampling operation to increase the dimension of the input. The up-sampling operation may include, for example, expansion and an interpolation filter, among others. In performing the up-sampling operation, the up-sampler 735 may insert null (or default) values into the input to expand the dimension. The insertion or null values may separate the pre-existing values. The up-sampler 735 may apply a filter (e.g., a low-pass frequency filter or another smoothing operation) to the expanded feature map. With the application, the up-sampler 735 may feed the resultant input into the transform layers 740.

The set of transform layers 740 can include one or more weights to modify or otherwise process the input to produce or generate an output. For example, the set of transform layers 740 may include at least one convolutional layer, at least one normalization layer, and at least one activation layer, among others. The set of transform layers 740 can be arranged in series, with an output of one transform layer 740 fed as an input to a succeeding transform layer 740. Each transform layer 740 may have a non-linear input-to-output characteristic. In some embodiments, the set of transform layers 740 may be a convolutional neural network (CNN). The convolutional layer, the normalization layer, and the activation layer (e.g., a rectified linear unit (ReLU)) may be arranged in accordance with the CNN architecture.

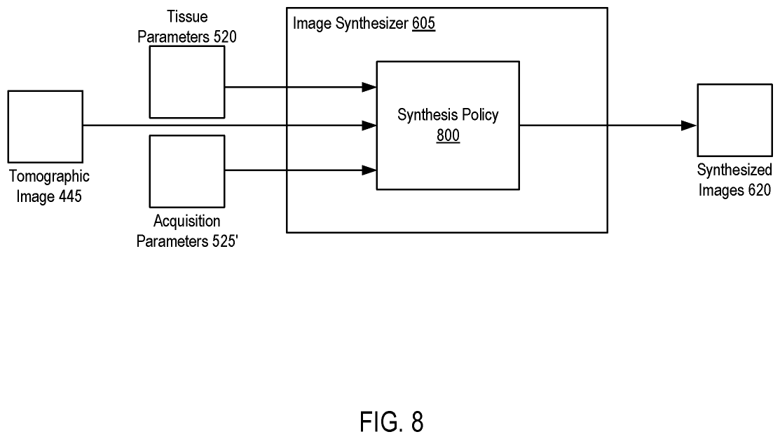

Referring now to FIG. 8, depicted is a block diagram of the image synthesizer 605 in the image segmentation model 430 of the system 400. The image synthesizer 605 may be configured with or may otherwise include at least one synthesis policy 800. The synthesis policy 800 may specify, identify, or otherwise define one or more relations among the parameters (e.g., the set of tissue parameters 520 and acquisition parameters 525 or 525′) with which to generate at least one synthesized tomographic image 620. For example, the synthesis policy 800 may be the Bloch equation as discussed herein in Section A. In general, the synthesis policy 800 may adjust or set a contrast of the synthesized tomographic image 620 from the tomographic image 445.

According to the synthesis policy 800, the model applier 425 may generate the synthesized tomographic image 620 using the tomographic image 445 (or the reconstructed tomographic image 445′), the tissue parameters 520, and the acquisition parameters 525′. In generating, the model applier 425 may identify the set of tissue parameters 520 associated with the tomographic image 445. In some embodiments, the model applier 425 may retrieve, extract, or identify the set of tissue parameters 520 associated with the tomographic image 445 from the training dataset 440. As discussed above, the tissue parameters 520 may be included in the training dataset 440 along with the tomographic images 445. In some embodiments, the model applier 425 may retrieve, receive, or identify the set of tissue parameters 520 from the tomograph 40 that provided the tomographic image 445. In addition, the model applier 425 may retrieve, receive, or identify the set of acquisition parameters 525′ from the generator 600. As discussed above, the sampler 710 of the generator 600 may provide the set of acquisition parameters 525′ from the distribution of features 715.

With the identification, the model applier 425 may process the tissue parameters 520, the acquisition parameters 525′, and the tomographic image 445 in accordance with the one or more relations specified by the synthesis policy 800. In some embodiments, the model applier 425 may feed the tissue parameters 520 and the acquisition parameters 525′ to the relations (e.g., Bloch equation) as defined by the synthesis policy 800 to generate a set of resultants. In some embodiments, the model applier 425 may use different weights of the tissue parameters 520 in applying the synthesis policy 800. The model applier 425 may apply the resultants to the tomographic image 445 to produce, output, and generate the synthesized tomographic image 620. With the output, the model applier 425 may feed the synthesized tomographic image 620 to the discriminator 610.

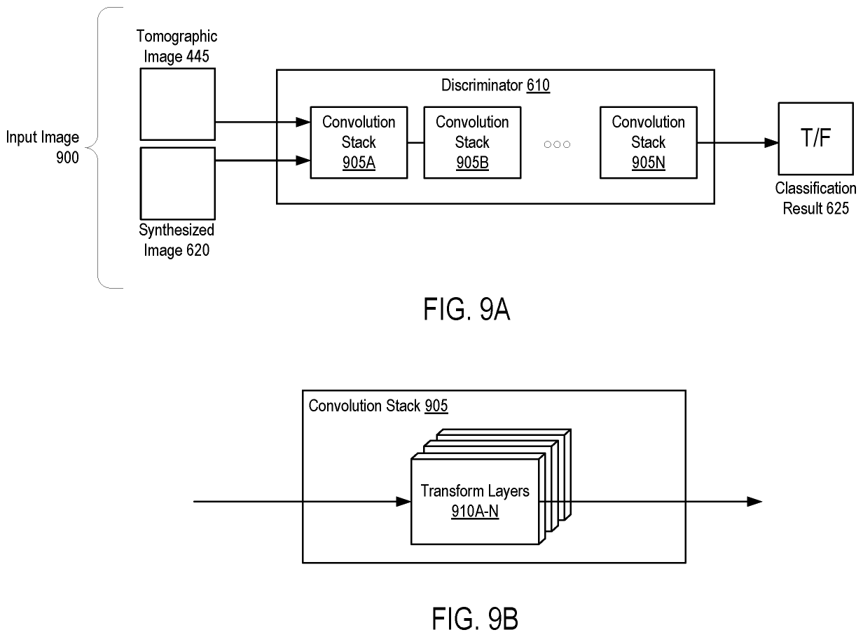

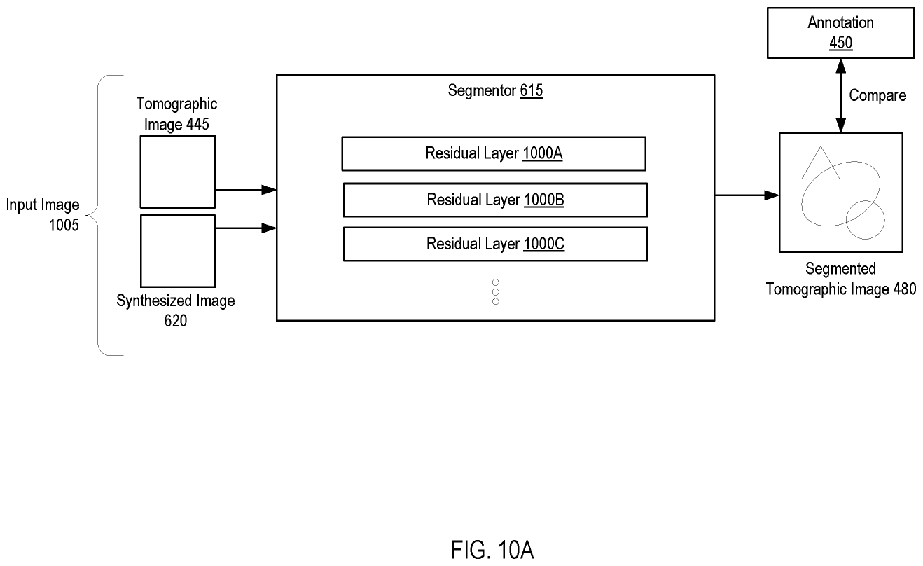

Referring now to FIG. 9A, depicted a block diagram of the discriminator 610 (sometimes referred herein as a discriminator network) in the image segmentation model 430 in the system 400. The discriminator 610 may include a set of convolution stacks 905A-N (hereinafter generally referred to as convolution stacks 905). The input and the output of the discriminator 610 may be related via a set of parameters define within the set of convolution stacks 905. The set of convolution stacks 905 can be arranged in series or parallel configuration, or in any combination. In parallel configuration, the input of one convolution stacks 905 may include the input of the entire discriminator 610. In a series configuration (e.g., as depicted), the input of one convolution stacks 905 may include the output of the previous convolution stacks 905. The input of the first convolution stack 905A may include at least one input tomographic image 900 corresponding to the original tomographic image 445 or the synthesized tomographic image 620 from the image synthesizer 605. The output of the last convolution stack 905N may be the classification result 625.

In training, the model applier 425 may identify or select one of the tomographic image 445 or the synthesized tomographic image 620 as the input image 900 to apply to the discriminator 610. The input image 900 may be associated with one of the weightings of the tissue parameters 520. With the identification, the model applier 425 may feed the input image 900 as the input to the discriminator 610 to determine whether the input image 900 is synthesized. The discriminator 610 may process the input image 900 in accordance with the weights of the discriminator 610 (e.g., as defined in the convolution stacks 905) to produce, output, or generate the classification result 625. The classification result 625 may indicate whether the input image 900 is synthesized (e.g., processed by the image synthesizer 605) or real (e.g., from the tomograph 410). For example, the classification result 625 may indicate the Boolean value of “false” when the input image 900 is determined to be synthesized. Conversely, the classification result 625 may indicate the Boolean value of “true” when the input image 900 is determined to be realistic. While training, the accuracy of the determination regarding the source of the input by the discriminator 610 may increase.

The model trainer 420 may establish and train the discriminator 610 based on the input image 900 and the classification result 625. To train, the model trainer 420 may compare the classification result 625 to the source for input image 900 provided to the discriminator 610. When the classification result 625 indicates that the input image 900 is realistic and the input image 900 is the synthesized tomographic image 620, the model trainer 420 determine that the classification result 625 is inaccurate. When the classification result 625 indicates that the input image 900 is synthetic and the input image 900 is the tomographic image 445, the model trainer 420 may also determine that the classification result 625 is inaccurate. Conversely, when the classification result 625 indicates that the input image 900 is realistic and the input image 900 is the tomographic image 445, the model trainer 420 determine that the classification result 625 is inaccurate. When the classification result 625 indicates that the input image 900 is synthetic and the input image 900 is the synthesized tomographic image 620, the model trainer 420 may also determine that the classification result 625 is accurate.

Based on the comparisons, the model trainer 420 may calculate, generate, or otherwise determine a loss metric (also referred herein as a matching loss) for the discriminator 610. The determination of the loss metric may be based on classification results 625 generated for the set of input images 900 with different weights of the tissue parameters 520. The loss metric may indicate or correspond to a degree of inaccuracy of the discriminator 610 in producing the correct classification results 625. The loss metric may be calculated in accordance with a loss function, such as a Kullback-Leibler (KL) divergence, Wasserstein loss function, a root mean squared error, a relative root mean squared error, and a weighted cross entropy, among others. In some embodiments, the model trainer 420 can calculate or determine the loss function by replicating a probability distribution. In general, when the inaccuracy is greater, the loss metric may be also greater. Conversely, when the inaccuracy is lower, the loss metric may also be lower.

Using the loss metric, the model trainer 420 may modify, configure, or otherwise update at least one of the weights in the generator 600 (e.g., the encoder 700 and the decoder 705) and the discriminator 610 (e.g., the set of convolution stacks 905). The loss metric may be back-propagated to update the weights in the generator 600 and the discriminator 610. The updating of weights may be in accordance with an optimization function (or an objective function) for the generator 600 and the discriminator 610. The optimization function may define one or more rates or parameters at which the weights of the generator 600 and the discriminator 610 are to be updated. For example, the model trainer 420 may use the optimization function with a set learning rate, a momentum, and a weight decay for a number of iterations in training. The updating of the weights may be repeated until a convergence condition. In iteratively updating the weights, the accuracy of the classification result 625 and the set of acquisition parameters 525′ to contrast the tomographic images 445 may be improved.

Referring now to FIG. 9B, depicted is a block diagram of the convolution stack 905 in the discriminator 610 in the image segmentation model in the system 400. Each convolution stack 905 may include a set of transform layers 910A-N (hereinafter generally referred to as transform layers 910). The set of transform layers 910 may be arranged in series or parallel configuration, or in any combination. The transform layers 910 may define or include the weights for the corresponding convolution stack 905 in the discriminator 610. The set of transform layers 910 can include one or more weights to modify or otherwise process the input to produce or generate an output set of features. For example, the set of transform layers 910 may include at least one convolutional layer, at least one normalization layer, and at least one activation layer, among others. The set of transform layers 910 can be arranged in series, with an output of one transform layer 910 fed as an input to a succeeding transform layer 910. Each transform layer 910 may have a non-linear input-to-output characteristic. In some embodiments, the set of transform layers 910 may be a convolutional neural network (CNN). The convolutional layer, the normalization layer, and the activation layer (e.g., a rectified linear unit (ReLU)) may be arranged in accordance with the CNN architecture.

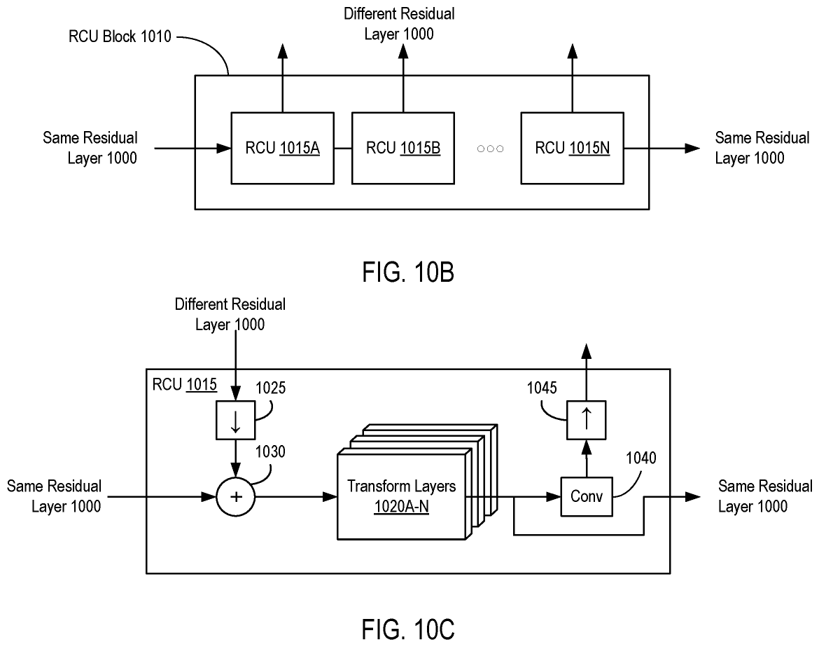

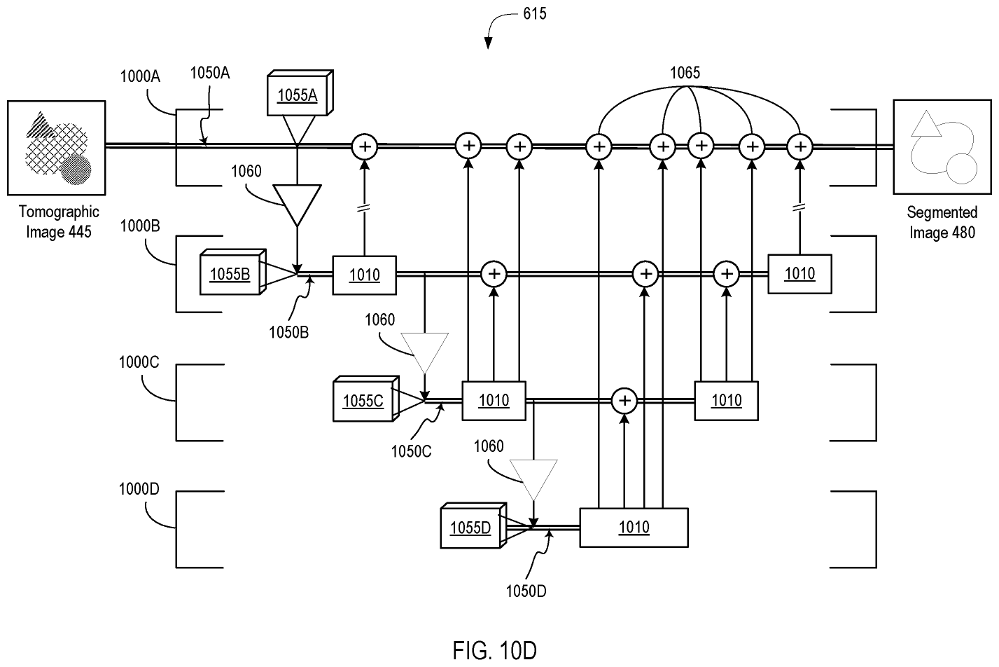

Referring now to FIG. 10A, depicted is a block diagram of the segmentor 615 (also referred herein as a segmentor network) in the image segmentation model 430 in the system 400. The segmentor 615 may include or maintain a set of residual layers 1000A-N (hereinafter generally referred to as residual layers 1000) arranged in a defined architecture. For example, the segmentor 615 may be configured as a multi-resolution residual network (MRRN) architecture (e.g., as discussed below). The input and the output of the segmentor 615 may be related via a set of parameters defined within the set of residual layers 1000. Each residual layer 1000 may correspond to a magnification factor or a resolution of features to be processed. In some embodiments, successive residual layers 1000 may correspond to lower magnifications or resolutions than previous residual layers 1000. For example, the first residual layer 1000A may correspond to a magnification factor of 10×, while the second residual layers 1000B may correspond to a magnification factor of 5×. The set of residual layers 1000 can be arranged in series or parallel configuration, or in any combination. The input of one or more of the residual layers 1000 may include at least one input tomographic image 1005 corresponding to the original tomographic image 445 or the synthesized tomographic image 620 from the image synthesizer 605. The output of the residual layers 1000 of the segmentor 615 may be the segmented tomographic image 480.

In training, the model applier 425 may identify or select one of the tomographic image 445 or the synthesized tomographic image 620 as the input image 1005 to apply to the discriminator 610. The input image 1005 may be associated with one of the weightings of the tissue parameters 520. With the identification, the model applier 425 may apply the input image 1005 to the segmentor 615 in accordance with architecture of the set of residual layers 1000. The model applier 425 may process the input image 1005 using the weights of the segmentor 615 (e.g., as defined using the set of residual layers 1000) to produce, output, or generate the segmented tomographic image 480. The segmented tomographic image 480 may identify the ROIs 515 corresponding to various features in the subject 500 under scan acquired in the input image 1005. In the illustrated example, the segmented tomographic image 480 may include an outline of the ROIs 515 corresponding to the features in the input image 1005.

The model trainer 420 may establish and train the segmentor 615 using the segmented tomographic image 480 and the annotation 450 for the tomographic image 445 used to generate the segmented tomographic image 480. As discussed above, the annotation 450 may label or identify one or more ROIs 515 within the associated tomographic image 445. In training, the model trainer 420 may compare the segmented tomographic image 480 and the annotation 450. Based on the comparison, the model trainer 420 may calculate, generate, or otherwise determine a loss metric. The loss metric may indicate or correspond a degree of deviation between the ROIs 515 identified by the segmented tomographic image 480 from the ROIs 515 identified by the annotation 450 (e.g., a pixel-by-pixel comparison). The loss metric may be determine accordance with a loss function, such as a Kullback-Leibler (KL) divergence, a root mean squared error, a relative root mean squared error, and a weighted cross entropy, among others. In general, when the degree of deviation is greater, the loss metric may be also greater. Conversely, when the degree of deviation is lower, the loss metric may be lower.

With the determination of the loss metric, the model trainer 420 may modify, configure, or otherwise update at least one of the weights in the generator 600 (e.g., the encoder 700 and the decoder 705), the discriminator 610 (e.g., the set of convolution stacks 905), and the segmentor 615 (e.g., the set of residual layers 1000). The loss metric may be back-propagated to update the weights in the generator 600, the discriminator 610, and the segmentor 615. The updating of weights may be in accordance with an optimization function (or an objective function) for the generator 600 and the discriminator 610. The optimization function may define one or more rates or parameters at which the weights of the generator 600, the discriminator 610, and the segmentor 615 are to be updated. For example, the model trainer 420 may use the optimization function with a set learning rate, a momentum, and a weight decay for a number of iterations in training. The updating of the weights may be repeated until a convergence condition. In updating the weights, the acquisition parameters 525′ to contrast the tomographic images 445 and the accuracy of the identification of ROIs 515 by the segmentor 615 may be improved.

Referring now to FIG. 10B, depicted is a block diagram of a residual connection unit (RCU) block 1010 in the segmentor 615 in the image segmentation model 430 of the system 400. One or more instances of the RCU block 1010 may be included into at least one of the residual layers 1000 of the segmentor 615. In some embodiments, the RCU blocks 1010 may be located in the second and subsequent residual layers 1000B-N and may be omitted from the first residual layer 100A. Each RCU block 1010 may include a set of residual connection units (RCUs) 1015A-N (hereinafter generally referred to as RCUs 1015). The input and the output of the RCU block 1010 may be related via a set of parameters defined within the set of RCUs 1015. The set of RCUs 1015 may be arranged in series or parallel configuration, or in any combination. In a series configuration (e.g., as depicted), the input of one RCUs 1015 may include the output of the previous RCUs 1015. The RCU block 1010 may have at least one input and a set of outputs. The input of RCU block 1010 may include features from the same residual layer 1000 as the RCU block 1010. Each RCU 1015 of the RCU block 1010 may define the outputs for the RCU block 1010. At least one output of the RCU block 1010 may be fed forward along the same residual layer 1000. One or more outputs of the RCU block 1010 may be fed to another residual layer 1000 (e.g., to a residual layer 1000 above as depicted).

Referring now to FIG. 10C, depicted is a block diagram of a residual connection unit (RCU) 1015 in a RCU block 1010 in the segmentor 615 in the image segmentation model 430 in the system 400. The RCU 1015 may include a set of transform layers 1020A-N (hereinafter generally referred to as transform layers 1020), at least one down-sampler 1025, at least one aggregation operator 1030, at least one convolution unit 1040, and at least one up-sampler 1045. Each RCU 1015 of the RCU 1010 may include one or more inputs and one or more outputs. The inputs may include features from the same residual layer 1000 and a different residual layer 1000 (e.g., one of the residual layers 1000 above the current residual layer 1000). The outputs may include features to be fed along the same residual layer 1000 and a different residual layer 1000 (e.g., one of the residual layers 1000 above the current residual layer 1000).

The down-sampler 1025 may retrieve, receive, or identify features from the different residual layer 1000. The down-sampler 1025 can reduce the resolution (or dimensions) of the features received from the previous residual layer 1000 to an resolution to fit the set of transform layers 1020. In some implementations, the down-sampler 1025 can apply a pooling operation to reduce the image resolution of the received features. The pooling operation can include, for example, max-pooling to select the highest value within each subset of features or mean-pooling to determine an average value within the subset in the features. In some embodiments, the down-sampler 1025 can apply a down sampling operation to the features.

The aggregation operator 1030 may retrieve, receive, or identify features from the same residual layer 1000 and features outputted by the down-sampler 1025 from a different residual layer 1000. The input from the same residual layer 1000 can include, for example, features. The features of the same residual layer 1000 can be of the resolution already fitting the set of transform layers 1020 in the RCU 1015. With receipt of both inputs, the input aggregation operator 1030 can combine the features from the down-sampler 134 and features from the same residual layer 1000 to generate features to input into the set of transform layers 1020. The combination of the features may include concatenation, weighted summation, and addition, among others.

The set of transform layers 1020 of the RCU 1015 may be arranged in series or parallel configuration, or in any combination. The transform layers 1020 may define or include the weights for the corresponding RCU 1015 in the RCU block 1010. The set of transform layers 1020 can include one or more weights to modify or otherwise process the input to produce or generate an output set of features. For example, the set of transform layers 1020 may include at least one convolutional layer, at least one normalization layer, and at least one activation layer, among others. The set of transform layers 1020 can be arranged in series, with an output of one transform layer 1020 fed as an input to a succeeding transform layer 1020. Each transform layer 1020 may have a non-linear input-to-output characteristic. In some embodiments, the set of transform layers 1020 may be a convolutional neural network (CNN). The convolutional layer, the normalization layer, and the activation layer (e.g., a rectified linear unit (ReLU)) may be arranged in accordance with the CNN architecture.

The convolution unit 1040 of the RCU 1015 may receive the set of features processed by the set of transform layers 1020. The set of features processed by the transform layers 1020 may have a size or dimension incompatible for processing by the previous residual layer 1000. For example, the set of features may have a depth beyond the compatible number for the previous residual layer 1116. Upon receipt, the convolution unit 1040 may apply a dimension reduction operator to the set of features from the set of transform layers 1020. The dimension reduction operator may include a 1×1 convolution, a 3×3 convolution, linear dimension reduction, and non-linear dimension reduction, among others. Application of the dimension reduction operator by the convolution unit 1040 may reduce the size or the reduction of the features. Upon application, the output of the convolution unit 1040 may be fed into the up-sampler 1045.

The up-sampler 1045 of the RCU 1015 may increase the image resolution of the input to increase a dimension (or resolution) to match the resolution of the features in the other residual layer 1000. In some implementations, the up-sampler 1045 can apply an up-sampling operation to increase the dimension of the input. The up-sampling operation may include, for example, expansion and an interpolation filter, among others. In performing the up-sampling operation, the up-sampler 1045 may insert null (or default) values into the input to expand the dimension. The insertion or null values may separate the pre-existing values. The up-sampler 1045 may apply a filter (e.g., a low-pass frequency filter or another smoothing operation) to the expanded feature map. With the application, the up-sampler 1045 may feed the resultant to the other residual layer 1000.

Referring now to FIG. 10D, depicted is a block diagram of the set of residual layers 1000 in the segmentor 615 of the image segmentation model 430. In the depiction, the segmentor 615 may include four residual layers 1000A-D, but the segmentor 615 may have any number of residual layers 1000. The various components, such as the residual layers 1000, the RU blocks 1010, the RCUs 1015, among others, may be connected with one another in the manner defined by the incremental MRRN architecture for the segmentor 615 (e.g., as depicted). Each residual layer 1000 may have a corresponding residual stream 1050A-N (hereinafter generally referred to as residual streams 1050). Each residual stream 1050 may carry or may be used to maintain a corresponding set of features 1055A-N (hereinafter generally referred to as features 1055). Each set of features 1055 may have the resolution (or dimension) associated with the corresponding residual layer 1000 and by extension the corresponding residual stream 1050.

The components of the segmentor 615 may reside on or defined relative to the respective residual layer 1000 or the residual stream 1050. In the illustrated example, each residual layer 1000B-D beneath the first residual layer 1000A may include one or more RCU blocks 1010. The input for each RCU block 1010 may be obtained from the same residual layer 1000. For instance, the RCU block 1010 in the second residual layer 1000B may be the set of features 1055B carried along the same residual layer 1000B. The output for one or more of the RCU blocks 1010 may be fed along the same residual layer 1000. The output for the RCU blocks 1010 may be also fed to a different residual layer 1000. For example, in the fourth residual layer 1000D, the RCU block 1010 may provide the output features to the other residual layers 100B-D.

In addition, the segmentor 615 may have one or more pooling units 1060. Each pooling unit 1060 may span between at least two of the residual layers 1000 and by extension at least two of the residual streams 1050. Each pooling unit 1060 may retrieve, receive, or otherwise identify features 1055 from one residual layer 1000 to reduce in resolution for processing by a succeeding residual layer 1000 (e.g., from the first residual layer 1000A to the second residual layer 1000B). The pooling unit 1060 may apply a pooling operation to the features 1055 identified from the residual layer 1000. The pooling operation can include, for example, max-pooling to select the highest value within each set patch in the feature map or mean-pooling to determine an average value within the set patch in the feature map. The features 1055 processed by the pooling unit 1060 may be of an resolution less than the resolution of the original features 1055 identified from the residual layer 1000.

The segmentor 615 may have one or more aggregation units 1065 along or within the respective residual streams 1050 of the residual layers 1000. The aggregator unit 1065 may receive input (e.g., the set of features 1055) from the residual stream 1050 of the same residual layer 1000 and the set of features 1055 from another residual layer 1000. Upon receipt of both inputs, the aggregator unit 1065 may combine features 1055 in the residual stream of the same residual layer 1000 and the features 1055 from the other residual layer 1000. The combination by the aggregator unit 1065 may generate features 1055 for further processing along the residual stream 1050. The combination of the features 1055 by the aggregation unit 1065 may include concatenation, weighted summation, and addition, among others.

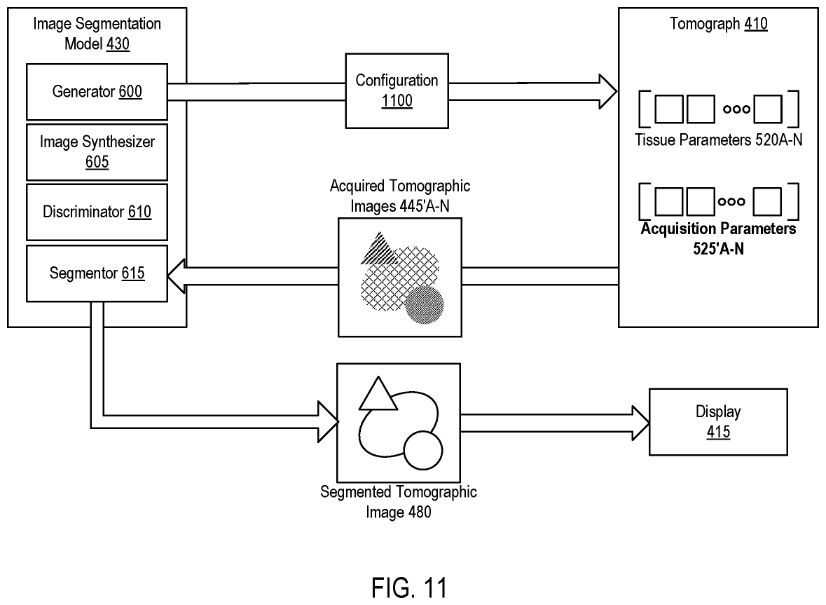

Referring now to FIG. 11, depicted is a block diagram of configuring the tomograph 410 upon establishment of the image segmentation model 430 in the system 400. With the completion of the training of the image segmentation model 430, the model trainer 420 may send, transmit, or otherwise provide at least one configuration 1100 to the tomograph 410. The configuration 1100 may identify or include the set of acquisition parameters 525′ from the generator 600 of the image segmentation model 430. In providing the configuration 1100, the model trainer 420 may identify the set of acquisition parameters 525′ via the sampler 710 of the generator 600. The model trainer 420 may retrieve or identify a distribution of acquisition parameters 525′ via the sampler 710 from the features 715 generated by the encoder 700 of the generator 600. Based on the distribution, the model trainer 420 may determine or generate the set of acquisition parameters 525′ to provide as the configuration 1100 to the tomograph 410.

Upon receipt of the configuration 1100, the tomograph 410 may store and maintain the set of acquisition parameters 525′. In storing, the tomograph 410 may replace the previous set of acquisition parameters 525. In general, the new set of acquisition parameters 525′ may yield tomographic images 445 with higher contrast relative to tomographic images 445 generated using the previous set of tomographic images 445. When in runtime mode, the tomograph 410 may provide a new set of tomographic images 445 from scanning a volume 505 of a subject 500. The model applier 425 may retrieve, receive, or identify the new set of tomographic images 445. The model applier 425 may process each tomographic image 445 as discussed above to produce, output, or generate the segmented tomographic image 480 for the respective tomographic image 445. The model applier 425 may provide the segmented tomographic image 480 via the output 475 to the display 415 for presentation. In some embodiments, the output 475 may also identify or include the original tomographic image 445 associated with the segmented tomographic image 480. The display 415 may be part of the tomogram segmentation system 405 or on another computing device that may be communicatively coupled to the tomogram segmentation system 405. The display 415 may present or render the output 475 upon receipt. For example, the display 415 may render a graphical user interface that shows the selected segmented image 480 and the acquired tomographic image 445.

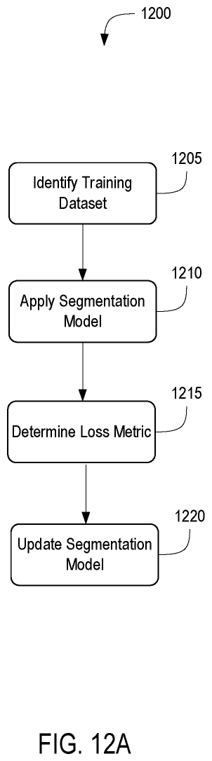

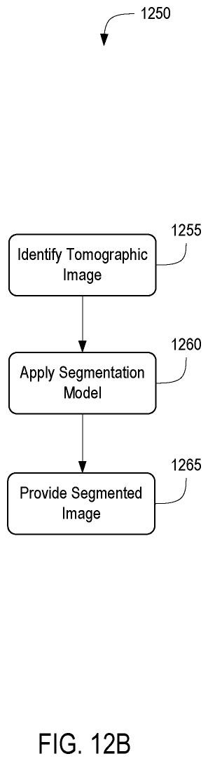

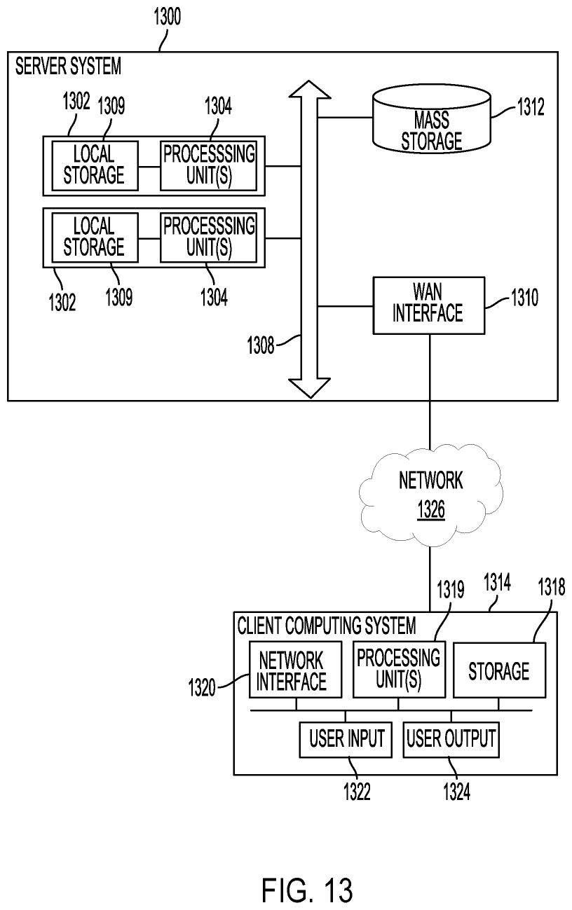

Referring now to FIG. 12A, depicted is a flow diagram of a method 1200 of training models to segment tomographic images. The method 1200 may be implemented using or performed by any of the components described herein, for example, the system 400 as described in conjunction with FIGS. 4-11 or the computing system as detailed in conjunction with FIG. 13. In overview, a computing system (e.g., the tomogram segmentation system 405) may identify a training dataset (e.g., the training dataset 440) (1205). The computing system may apply a segmentation model (e.g., the image segmentation model 430) (1210). The computing system may determine a loss metric (1215). The computing system may update the segmentation model (1220).

Referring now to FIG. 12B, depicted is a flow diagram of a method 1250 of applying models to segment tomographic images. The method 1250 may be implemented using or performed by any of the components described herein, for example, the system 400 as described in conjunction with FIGS. 4-11 or the computing system as detailed in conjunction with FIG. 13. In overview, a computing system (e.g., the tomogram segmentation system 405) may identify a tomographic image (e.g., the tomographic image 455) (1255). The computing system may apply a segmentation model (e.g., the image segmentation model 430) (1260). The computing system may provide a segmented image (e.g., the segmented tomographic image 480) (1265).

### C. Computing and Network Environment

Various operations described herein can be implemented on computer systems. FIG. 13 shows a simplified block diagram of a representative server system 1300, client computer system 1314, and network 1326 usable to implement certain embodiments of the present disclosure. In various embodiments, server system 1300 or similar systems can implement services or servers described herein or portions thereof. Client computer system 1314 or similar systems can implement clients described herein. The system 400 described herein can be similar to the server system 1300. Server system 1300 can have a modular design that incorporates a number of modules 1302 (e.g., blades in a blade server embodiment); while two modules 1302 are shown, any number can be provided. Each module 1302 can include processing unit(s) 1304 and local storage 1306.

Processing unit(s) 1304 can include a single processor, which can have one or more cores, or multiple processors. In some embodiments, processing unit(s) 1304 can include a general-purpose primary processor as well as one or more special-purpose co-processors such as graphics processors, digital signal processors, or the like. In some embodiments, some or all processing units 1304 can be implemented using customized circuits, such as application specific integrated circuits (ASICs) or field programmable gate arrays (FPGAs). In some embodiments, such integrated circuits execute instructions that are stored on the circuit itself. In other embodiments, processing unit(s) 1304 can execute instructions stored in local storage 1306. Any type of processors in any combination can be included in processing unit(s) 1304.

Local storage 1306 can include volatile storage media (e.g., DRAM, SRAM, SDRAM, or the like) and/or non-volatile storage media (e.g., magnetic or optical disk, flash memory, or the like). Storage media incorporated in local storage 1306 can be fixed, removable or upgradeable as desired. Local storage 1306 can be physically or logically divided into various subunits such as a system memory, a read-only memory (ROM), and a permanent storage device. The system memory can be a read-and-write memory device or a volatile read-and-write memory, such as dynamic random-access memory. The system memory can store some or all of the instructions and data that processing unit(s) 1304 for runtime. The ROM can store static data and instructions that are to be processed by processing unit(s) 1304. The permanent storage device can be a non-volatile read-and-write memory device that can store instructions and data even when module 1302 is powered down. The term “storage medium” as used herein includes any medium in which data can be stored indefinitely (subject to overwriting, electrical disturbance, power loss, or the like) and does not include carrier waves and transitory electronic signals propagating wirelessly or over wired connections.

In some embodiments, local storage 1306 can store one or more software programs to be executed by processing unit(s) 1304, such as an operating system and/or programs implementing various server functions such as functions of the system 400 of FIG. 4 or any other system described herein, or any other server(s) associated with system 400 or any other system described herein.

“Software” refers generally to sequences of instructions that, when executed by processing unit(s) 1304 cause server system 1300 (or portions thereof) to perform various operations, thus defining one or more specific machine embodiments that execute and perform the operations of the software programs. The instructions can be stored as firmware residing in read-only memory and/or program code stored in non-volatile storage media that can be read into volatile working memory for execution by processing unit(s) 1304. Software can be implemented as a single program or a collection of separate programs or program modules that interact as desired. From local storage 1306 (or non-local storage described below), processing unit(s) 1304 can retrieve program instructions to execute and data to process in order to execute various operations described above.

In some server systems 1300, multiple modules 1302 can be interconnected via a bus or other interconnect 1308, forming a local area network that supports communication between modules 1302 and other components of server system 1300. Interconnect 1308 can be implemented using various technologies including server racks, hubs, routers, etc.

A wide area network (WAN) interface 1310 can provide data communication capability between the local area network (interconnect 1308) and the network 1326, such as the Internet. Technologies can be used, including wired (e.g., Ethernet, IEEE 1302.3 standards) and/or wireless technologies (e.g., Wi-Fi, IEEE 1302.11 standards).

In some embodiments, local storage 1306 is intended to provide working memory for processing unit(s) 1304, providing fast access to programs and/or data to be processed while reducing traffic on interconnect 1308. Storage for larger quantities of data can be provided on the local area network by one or more mass storage subsystems 1312 that can be connected to interconnect 1308. Mass storage subsystem 1312 can be based on magnetic, optical, semiconductor, or other data storage media. Direct attached storage, storage area networks, network-attached storage, and the like can be used. Any data stores or other collections of data described herein as being produced, consumed, or maintained by a service or server can be stored in mass storage subsystem 1312. In some embodiments, additional data storage resources may be accessible via WAN interface 1310 (potentially with increased latency).

Server system 1300 can operate in response to requests received via WAN interface 1310. For example, one of modules 1302 can implement a supervisory function and assign discrete tasks to other modules 1302 in response to received requests. Work allocation techniques can be used. As requests are processed, results can be returned to the requester via WAN interface 1310. Such operation can generally be automated. Further, in some embodiments, WAN interface 1310 can connect multiple server systems 1300 to each other, providing scalable systems capable of managing high volumes of activity. Other techniques for managing server systems and server farms (collections of server systems that cooperate) can be used, including dynamic resource allocation and reallocation.

Server system 1300 can interact with various user-owned or user-operated devices via a wide-area network such as the Internet. An example of a user-operated device is shown in FIG. 13 as client computing system 1314. Client computing system 1314 can be implemented, for example, as a consumer device such as a smartphone, other mobile phone, tablet computer, wearable computing device (e.g., smart watch, eyeglasses), desktop computer, laptop computer, and so on.

For example, client computing system 1314 can communicate via WAN interface 1310. Client computing system 1314 can include computer components such as processing unit(s) 1316, storage device 1318, network interface 1320, user input device 1322, and user output device 1324. Client computing system 1314 can be a computing device implemented in a variety of form factors, such as a desktop computer, laptop computer, tablet computer, smartphone, other mobile computing device, wearable computing device, or the like.

Processor 1316 and storage device 1318 can be similar to processing unit(s) 1304 and local storage 1306 described above. Suitable devices can be selected based on the demands to be placed on client computing system 1314; for example, client computing system 1314 can be implemented as a “thin” client with limited processing capability or as a high-powered computing device. Client computing system 1314 can be provisioned with program code executable by processing unit(s) 1316 to enable various interactions with server system 1300.

Network interface 1320 can provide a connection to the network 1326, such as a wide area network (e.g., the Internet) to which WAN interface 1310 of server system 1300 is also connected. In various embodiments, network interface 1320 can include a wired interface (e.g., Ethernet) and/or a wireless interface implementing various RF data communication standards such as Wi-Fi, Bluetooth, or cellular data network standards (e.g., 3G, 4G, LTE, etc.).

User input device 1322 can include any device (or devices) via which a user can provide signals to client computing system 1314; client computing system 1314 can interpret the signals as indicative of particular user requests or information. In various embodiments, user input device 1322 can include any or all of a keyboard, touch pad, touch screen, mouse or other pointing device, scroll wheel, click wheel, dial, button, switch, keypad, microphone, and so on.

User output device 1324 can include any device via which client computing system 1314 can provide information to a user. For example, user output device 1324 can include a display to display images generated by or delivered to client computing system 1314. The display can incorporate various image generation technologies, e.g., a liquid crystal display (LCD), light-emitting diode (LED) including organic light-emitting diodes (OLED), projection system, cathode ray tube (CRT), or the like, together with supporting electronics (e.g., digital-to-analog or analog-to-digital converters, signal processors, or the like). Some embodiments can include a device such as a touchscreen that functions as both input and output device. In some embodiments, other user output devices 1324 can be provided in addition to or instead of a display. Examples include indicator lights, speakers, tactile “display” devices, printers, and so on.

Some embodiments include electronic components, such as microprocessors, storage and memory that store computer program instructions in a computer readable storage medium. Many of the features described in this specification can be implemented as processes that are specified as a set of program instructions encoded on a computer readable storage medium. When these program instructions are executed by one or more processing units, they cause the processing unit(s) to perform various operations indicated in the program instructions. Examples of program instructions or computer code include machine code, such as is produced by a compiler, and files including higher-level code that are executed by a computer, an electronic component, or a microprocessor using an interpreter. Through suitable programming, processing unit(s) 1304 and 1316 can provide various functionality for server system 1300 and client computing system 1314, including any of the functionality described herein as being performed by a server or client, or other functionality.

It will be appreciated that server system 1300 and client computing system 1314 are illustrative and that variations and modifications are possible. Computer systems used in connection with embodiments of the present disclosure can have other capabilities not specifically described here. Further, while server system 1300 and client computing system 1314 are described with reference to particular blocks, it is to be understood that these blocks are defined for convenience of description and are not intended to imply a particular physical arrangement of component parts. For instance, different blocks can be but need not be located in the same facility, in the same server rack, or on the same motherboard. Further, the blocks need not correspond to physically distinct components. Blocks can be configured to perform various operations, e.g., by programming a processor or providing appropriate control circuitry, and various blocks might or might not be reconfigurable depending on how the initial configuration is obtained. Embodiments of the present disclosure can be realized in a variety of apparatus including electronic devices implemented using any combination of circuitry and software.

While the disclosure has been described with respect to specific embodiments, one skilled in the art will recognize that numerous modifications are possible. Embodiments of the disclosure can be realized using a variety of computer systems and communication technologies including but not limited to specific examples described herein. Embodiments of the present disclosure can be realized using any combination of dedicated components and/or programmable processors and/or other programmable devices. The various processes described herein can be implemented on the same processor or different processors in any combination. Where components are described as being configured to perform certain operations, such configuration can be accomplished, e.g., by designing electronic circuits to perform the operation, by programming programmable electronic circuits (such as microprocessors) to perform the operation, or any combination thereof. Further, while the embodiments described above may make reference to specific hardware and software components, those skilled in the art will appreciate that different combinations of hardware and/or software components may also be used and that particular operations described as being implemented in hardware might also be implemented in software or vice versa.

Computer programs incorporating various features of the present disclosure may be encoded and stored on various computer readable storage media; suitable media include magnetic disk or tape, optical storage media such as compact disk (CD) or DVD (digital versatile disk), flash memory, and other non-transitory media. Computer readable media encoded with the program code may be packaged with a compatible electronic device, or the program code may be provided separately from electronic devices (e.g., via Internet download or as a separately packaged computer-readable storage medium).

Thus, although the disclosure has been described with respect to specific embodiments, it will be appreciated that the disclosure is intended to cover all modifications and equivalents within the scope of the following claims.

What is claimed is:

1. A method of training models to segment tomographic biomedical images, comprising:
identifying, by a computing system, a training dataset having: a plurality of sample tomographic biomedical images acquired from a section of a subject, a plurality of tissue parameters associated with the section of the subject, and an annotation identifying at least one region on the section in at least one of the plurality of sample tomographic biomedical images;
training, by the computing system, an image segmentation model using the training dataset, the image segmentation model comprising:
a generator to determine a plurality of acquisition parameters using the plurality of sample tomographic biomedical images, the plurality of acquisition parameters defining an acquisition of the plurality of sample tomographic biomedical images from the section of the subject;
an image synthesizer to generate a plurality of synthesized tomographic biomedical images in accordance with the plurality of tissue parameters and the plurality of acquisition parameters;
a discriminator to determine a classification result indicating whether an input tomographic biomedical image corresponding to one of the plurality of sample tomographic biomedical image or the plurality of synthesized tomographic biomedical images is synthesized; and
a segmentor to generate, using the input tomographic biomedical image, a segmented biomedical image identifying the at least one region in the section of the subject; and
storing, by the computing system, the image segmentation model for use to identify one or more regions of interest in tomographic biomedical images.

2. The method of claim 1, wherein training the image segmentation model further comprises:
determining a segmentation loss metric based on the segmented tomographic biomedical image and the annotation; and
updating one or more parameters of at least one of the generator, the discriminator, and the segmentor of the image segmentation model using the segmentation loss metric.

3. The method of claim 1, wherein training the image segmentation model further comprises:
determining a matching loss metric based on the plurality of sample tomographic biomedical image and the corresponding plurality of synthesized tomographic biomedical image; and
updating one or more parameters of at least one of the generator, the discriminator, and the segmentor of the image segmentation model using the matching loss metric.

4. The method of claim 1, wherein training the image segmentation model further comprises updating one or more parameters of at least one of the generator and the discriminator using a loss metric associated with the segmentor.

5. The method of claim 1, wherein storing the image segmentation model further comprises providing, responsive to training of the image segmentation model, the plurality of acquisition parameters for acquisition of the tomographic biomedical images, the plurality of acquisition parameters identifying at least one of a flip angle (FA), a repetition time (TR), or an echo time (TE).

6. The method of claim 1, wherein the segmentor of the image segmentation model comprises a plurality of residual layers corresponding to a plurality of resolutions to generate the segmented tomographic biomedical image, each of the plurality of residual layers having one or more residual connection units (RCUs) to process at least one feature map for a corresponding resolution of the plurality of resolutions.

7. The method of claim 1, wherein each of the plurality of sample tomographic biomedical images is acquired from the section of the subject in vivo via magnetic resonance imaging, the plurality of tissue parameters identifying at least one of proton density (PD), a longitudinal relaxation time (T1), or a transverse relaxation time (T2) for the acquisition of the plurality of sample tomographic biomedical images.

8. A method of segmenting tomographic biomedical images, comprising:
identifying, by a computing system, a plurality of acquisition parameters derived from training of an image segmentation model and defining an acquisition of tomographic biomedical images;
receiving, by the computing system, a plurality of tomographic biomedical images of a sample of a subject using the plurality of acquisition parameters and a plurality of tissue parameters, the plurality of tissue parameters associated with the section of the subject corresponding to the plurality of tomographic biomedical images, the section having at least one region of interest;
applying, by the computing system, the image segmentation model to the plurality of tomographic biomedical images to generate a segmented tomographic biomedical image; and
storing, by the computing system, the segmented tomographic biomedical image identifying the at least one region of interest on the section of the subject.

9. The method of claim 8, further comprising establishing, by the computing system, the image segmentation model comprising a generator to determine the plurality of acquisition parameters, an image synthesizer to generate at least one synthesized tomographic biomedical image, a discriminator to determine whether an input tomographic biomedical image is synthesized, using a training dataset comprising a sample tomographic biomedical image and an annotation identifying at least one region of interest tomographic within the sample biomedical image.

10. The method of claim 9, wherein establishing the image segmentation model further comprises updating one or more parameters of the generator, the discriminator, and the segmentor using a loss metric, the loss metric including at least one of a segmentation loss metric or a matching loss metric.

11. The method of claim 8, wherein applying the image segmentation model further comprises applying a segmentor of the image segmentation model to the plurality of tomographic biomedical images, without applying a generator, an image synthesizer, and a discriminator used to train the image segmentation model based on a training dataset.

12. The method of claim 8, wherein the image segmentation model comprises a segmentor, the segmentor comprising a plurality of residual layers corresponding to a plurality of resolutions to generate the segmented tomographic biomedical image, each of the plurality of residual layers having one or more residual connection units (RCUs) to process at least one feature map for a corresponding resolution of the plurality of resolutions.

13. The method of claim 8, further comprising providing, to a magnetic resonance imaging (MRI) device, the plurality of acquisition parameters for the acquisition the plurality of tomographic biomedical image, the plurality of acquisition parameters identifying at least one a flip angle (FA), a repetition time (TR), or an echo time (TE), the plurality of tissue parameters identifying at least one of a proton density (PD), a longitudinal relaxation time (T1), or a transverse relaxation time (T2).

14. A system for training models to segment tomographic biomedical images, comprising:
a computing system having one or more processors coupled with memory, configured to:
identify a training dataset having: a plurality of sample tomographic biomedical images acquired from a section of a subject, a plurality of tissue parameters associated with the section of subject, and an annotation identifying at least one region on the section in at least one of the plurality of sample tomographic biomedical images;
train an image segmentation model using the training dataset, the image segmentation model comprising:
a generator to determine a plurality of acquisition parameters using the plurality of sample tomographic biomedical images, the plurality of acquisition parameters defining an acquisition of the plurality of sample tomographic biomedical images from the tissue sample;
an image synthesizer to generate a plurality of synthesized tomographic biomedical images in accordance with the plurality of tissue parameters and the plurality of acquisition parameters;
a discriminator to determine a classification result indicating whether an input biomedical image corresponding to one of the plurality of sample tomographic biomedical image or the plurality of synthesized tomographic biomedical images is synthesized; and
a segmentor to generate, using the input biomedical image, a segmented biomedical image identifying the at least one region on the section of the subject; and
store the image segmentation model for use to identify one or more regions of interest in tomographic biomedical images.

15. The system of claim 14, wherein the computing system is further configured to train the image segmentation model by:
determining a segmentation loss metric based on the segmented tomographic biomedical image and the annotation; and
updating one or more parameters of at least one of the generator, the discriminator, and the segmentor of the image segmentation model using the segmentation loss metric.

16. The system of claim 14, wherein the computing system is further configured to train the image segmentation model by:
determining a matching loss metric based on the plurality of sample tomographic biomedical image and the corresponding plurality of synthesized tomographic biomedical image; and
updating one or more parameters of at least one of the generator, the discriminator, and the segmentor of the image segmentation model using the matching loss metric.

17. The system of claim 14, wherein the computing system is further configured to train the image segmentation model by updating one or more parameters of at least one of the generator and the discriminator using a loss metric associated with the segmentor.

18. The system of claim 14, wherein the computing system is further configured to provide, responsive to training of the image segmentation model, the plurality of acquisition parameters for acquisition of the tomographic biomedical images, the plurality of acquisition parameters identifying at least one of a flip angle (FA), a repetition time (TR), or an echo time (TE).

19. The system of claim 14, wherein the segmentor of the image segmentation model comprises a plurality of residual layers corresponding to a plurality of resolutions to generate the segmented tomographic biomedical image, each of the plurality of residual layers having one or more residual connection units (RCUs) to process at least one feature map for a corresponding resolution of the plurality of resolutions.

20. The system of claim 14, wherein each of the plurality of sample tomographic biomedical images is acquired from the section of the subject in vivo via magnetic resonance imaging, the plurality of tissue parameters identifying at least one of proton density (PD), a longitudinal relaxation time (T1), or a transverse relaxation time (T2) for the acquisition of the plurality of sample tomographic biomedical images.
